(19) United States
(12) Patent Application Publication
(10) Pub. No.: US 2024/0324106 A1
(43) Pub. Date: Sep. 26, 2024

(54) SYSTEM AND METHOD OF FABRICATING OBJECTS USING ADDITIVE MANUFACTURING WITH REDUCED INTERFERENCE AND NOISE

(71) Applicant: Advanced Printed Electronic Solutions LLC, Fishkill, NY (US)

(72) Inventor: Richard Neill, Garrison, NY (US)

(21) Appl. No.: 18/611,144

(22) Filed: Mar. 20, 2024

Related U.S. Application Data
(60) Provisional application No. 63/453,394, filed on Mar. 20, 2023.

(51) Int. Cl. H05K 3/10; B33Y 10/00; H05K 1/02; H05K 3/46

(52) U.S. Cl. CPC H05K 3/108; H05K 1/0218; H05K 1/0242; H05K 3/4682; B33Y 10/00

(57) ABSTRACT

A method of fabricating an object is provided. The method includes fabricating a base structure. A first electrical component is deposited or fabricated on or in the base structure. At least one insulation material is deposited to define a first layer on the base structure that is associated with the first electrical component and positioned to reduce electrical noise and/or magnetic field interference.

### CROSS-REFERENCE TO RELATED APPLICATIONS

The present application claims the benefit of, and is a nonprovisional application of, U.S. Provisional Application Ser. No. 63/453,394 filed Mar. 20, 2023 entitled System and Method of Fabricating Objects Using Additive Manufacturing With Reduced Interference and Noise, the contents of which are incorporated by reference herein.

### BACKGROUND OF THE DISCLOSURE

The subject matter disclosed herein relates to a system and method of fabricating objects, and in particular to and method of using additive manufacturing processes to fabricate objects having integral circuits that has reduced and are immune to electrical noise and/or magnetic field interference. The subject matter disclosed herein further relates to fabricating objects with integral circuits while providing immunity and reduction to noise and magnetic field effects, the methods disclosed may also be utilized for fabricating objects with integral circuits that are tamper proof and/or preventing the reverse engineering by increasing the difficulty for external probe, measurement, and scanning devices to determine the design and operation of the underlying object and its integral circuits.

Some systems, such as those incorporating one or more antenna devices for example, are complicated to construct. In part this is due to the need to shield components, signal circuits, and busses, from outside interference avoid saturating sensitive sensors or undesirable signal coupling to one or more devices within the assembly or used in the system. As one example, an antenna array as part of a Magnetic Resonance Imaging (MRI) head scanner system is shown in FIG. 2G and FIG. 2H. This implementation results in shielded cabling being used to interconnect circuits. Due to the number of antennas in the system, the cabling must be carefully and manually installed. It should be appreciated that given the number of connections, this is a costly and time-consuming device to manufacture, which inhibits or prevents widespread adoption of these technologies.

While existing systems and processes for fabricating objects are suitable for their intended purposes the need for improvement remains, particularly in providing system and method of fabricating objects that has one or more of the features described herein.

### BRIEF DESCRIPTION OF THE DISCLOSURE

According to one aspect of the disclosure a method of fabricating an object is provided. The method includes fabricating a base structure using an additive manufacturing process. A first electrical component is deposited or fabricated on or in the base structure. At least one material is deposited to define a ground layer on the base structure that is associated with the first electrical component and positioned to reduce electrical noise, RF signals, microwave signals, and/or magnetic field interference.

In addition to one or more of the features described herein, or as an alternative, further embodiments of the method may include the first electrical component being a coil, an antenna, a conductor, a buss, a signal circuit, an electro-mechanical device, electro-chemical device, an integrated circuit or a field programmable gate array.

In addition to one or more of the features described herein, or as an alternative, further embodiments of the method may include the depositing of at least one insulation material i over the first electrical component with an additive manufacturing process, the layer including at least one via.

In addition to one or more of the features described herein, or as an alternative, further embodiments of the method may include depositing a ground layer over the insulation material.

In addition to one or more of the features described herein, or as an alternative, further embodiments of the method may include cutting access pockets for the via, and connecting the ground layer to a ground circuit.

In addition to one or more of the features described herein, or as an alternative, further embodiments of the method may include depositing a second insulation layer over the ground layer with the additive manufacturing process.

In addition to one or more of the features described herein, or as an alternative, further embodiments of the method may include depositing a second circuit material to define a signal circuit with the additive manufacturing process, the signal circuit having an input port and an output port.

In addition to one or more of the features described herein, or as an alternative, further embodiments of the method may include depositing a third insulation layer over the signal circuit with the additive manufacturing process, the third insulation layer being formed with at least two vias associated with the input port and the output port.

In addition to one or more of the features described herein, or as an alternative, further embodiments of the method may include depositing a second ground layer over the third insulation layer with the additive manufacturing process, the second ground layer having at least two vias aligned with the input port and the output port.

In addition to one or more of the features described herein, or as an alternative, further embodiments of the method may include depositing a fourth insulation layer over the second ground layer with the additive manufacturing process, the fourth insulation layer having at least two vias aligned with the input port and the output port.

In addition to one or more of the features described herein, or as an alternative, further embodiments of the method may include the first ground layer being made from one or more materials selected from a group comprising: silver, copper, lead, graphite, graphene, and pyrolytic carbon.

In addition to one or more of the features described herein, or as an alternative, further embodiments of the method may include repeating the steps described above.

In addition to one or more of the features described herein, or as an alternative, further embodiments of the method may include the first layer being formed with a three-dimensional shape.

In addition to one or more of the features described herein, or as an alternative, further embodiments of the method may include depositing a first ground layer associated with the first electrical component with the additive manufacturing process.

In addition to one or more of the features described herein, or as an alternative, further embodiments of the method may include the first ground layer being disposed on at least two sides of the first electrical component.

In addition to one or more of the features described herein, or as an alternative, further embodiments of the method may include the first ground layer being disposed on at least three sides of the first electrical component.

In addition to one or more of the features described herein, or as an alternative, further embodiments of the method may include the first ground layer being on at least fourth sides of the first electrical component.

In addition to one or more of the features described herein, or as an alternative, further embodiments of the method may include the first ground layer enclosing the first electrical component.

In addition to one or more of the features described herein, or as an alternative, further embodiments of the method may include the first ground layer being disposed within the base structure.

In addition to one or more of the features described herein, or as an alternative, further embodiments of the method may include the first electrical component being disposed within the base structure.

In addition to one or more of the features described herein, or as an alternative, further embodiments of the method may include the first electrical component being enclosed by the first ground layer within the base structure.

In addition to one or more of the features described herein, or as an alternative, further embodiments of the method may include at least one of the first electrical component and first ground layer having an cross-sectional geometry that varies in three-dimensional space.

In accordance with another aspect of the disclosure, a method of A method of fabricating an object is provided. The method includes fabricating a base structure using an additive manufacturing process. A first electrical component or electrical circuit is deposited on or adjacent to the first insulation layer. A first insulation layer is deposited adjacent the grounding layer with the additive manufacturing process. A grounding layer is deposited adjacent the insulation layer using the additive manufacturing process, the grounding layer being electrically coupled to the first electrical component or electrical circuit. At least one second insulation layer is deposited with the additive manufacturing process adjacent the grounding layer, the at least one second insulation layer being positioned to reduce electrical noise and/or magnetic field interference from being transmitted therethrough.

In addition to one or more of the features described herein, or as an alternative, further embodiments of the method may include forming at least one first via through the at least one second insulation layer. Conductive materials are deposited in the at least one first via. The grounding layer is electrically coupled to the first electrical component or electrical circuit through the at least one first via.

In addition to one or more of the features described herein, or as an alternative, further embodiments of the method may include forming at least one second via in the second insulation layer with the additive manufacturing process. The at one second via is filled with a conductive material. A signal circuit layer is deposited on the second insulation layer, the signal circuit being electrically coupled to the at least one second via.

In addition to one or more of the features described herein, or as an alternative, further embodiments of the method may include depositing a third insulation layer on the signal circuit layer with the additive manufacturing process, the third insulation layer being formed with at least one input/output port via. A second grounding layer is deposited on the third insulation layer, the second grounding layer leaving the at least one input/output port exposed. A fourth insulation layer is deposited on the second grounding layer with the additive manufacturing process.

These and other advantages and features will become more apparent from the following description taken in conjunction with the drawings.

### BRIEF DESCRIPTION OF DRAWINGS

The subject matter, which is regarded as the disclosure, is particularly pointed out and distinctly claimed in the claims at the conclusion of the specification. The foregoing and other features, and advantages of the disclosure are apparent from the following detailed description taken in conjunction with the accompanying drawings in which:

FIGS. 1A-1F are schematic views of prior art circuits that may be fabricated using additive methods in accordance with an embodiment;

FIG. 2A-2F are schematic views of prior art coil or antenna arrays that may be fabricated using additive methods in accordance with an embodiment;

FIG. 2G and FIG. 2H are perspective view illustrations of a prior art magnetic resonance imaging (MRI) wearable device having coils and interconnections;

FIG. 3A and FIG. 3B are perspective views of coil arrays, fabricated using additive methods according to one or more embodiments;

FIG. 4A and FIG. 4B are examples of antenna arrays fabricated using additive methods in accordance with an embodiment;

FIG. 5A-5D are examples of array configurations fabricated using additive methods in accordance with one or more embodiments;

FIG. 5E and FIG. 5F are examples of an additive manufacturing based approach to a 3-dimensional assembly of electronic or electrical component devices and circuits;

FIG. 6A and FIG. 6B are additive systems for fabricating objects accordance with another embodiment;

FIG. 7A-7R are schematic sectional views of structures having circuits, insulation and grounding layers fabricated using additive methods according to one or more embodiments;

FIGS. 8A-8E are schematic sectional views of various examples of shield structures in accordance with one or more embodiments;

FIG. 9A-9B are schematic sectional views of additional shield structures in accordance with one or more embodiments;

FIGS. 10A-10D are schematic sectional views of examples of embedded shielding structures in accordance with one or more embodiments;

FIGS. 11A-11G are schematic views of Faraday cages fabricated using additive methods in accordance with one or more embodiments;

FIG. 12 is a method of fabricating a device having circuits, insulation layers and ground layers additively deposited in accordance with an embodiment;

FIGS. 13A-13I are schematic views illustrating a fabrication using additive methods of a device using the method of FIG. 12 in accordance with an embodiment;

FIGS. 14A and 14B are schematic views of a first alternative insulation configuration in accordance with another embodiment; and

FIG. 15A-15C are schematic views of a second alternative insulation configuration in accordance with another embodiment.

The detailed description explains embodiments of the disclosure, together with advantages and features, by way of example with reference to the drawings.

### DETAILED DESCRIPTION OF THE DISCLOSURE

Embodiments of the present disclosure provide for the fabrication using additive methods to fabricate devices having integral structure, circuits, insulation and grounding. Embodiments provide for providing multi-material additive manufacturing methods for fabricating devices incorporating structural electronics that reduce electrical noise and magnetic field interference. Embodiments provide for using additive manufacturing methods for fabricating systems that utilize one or more integrally fabricated signal circuits, parallel busses, antenna, antenna arrays, coils, multi-coil arrays.

Embodiments herein describe the deposition or adding of materials using additive manufacturing systems. The objects fabricated may include grounding, insulation, dielectric, conductive, and/or structural materials. The deposition of materials (e.g. insulating, dielectrics, and/or conductors) can be any known material suitable for the application, such as but not limited to polymer filament, pastes or inks for example. The tools used in the fabrication can include but are not limited to extruders, jetting, aerosol, inkjet, or a combination of the foregoing for example. It should be appreciated that while individual embodiments may refer to a particular material or manufacturing tool, this is for the purpose of clarity and not intended to be limiting.

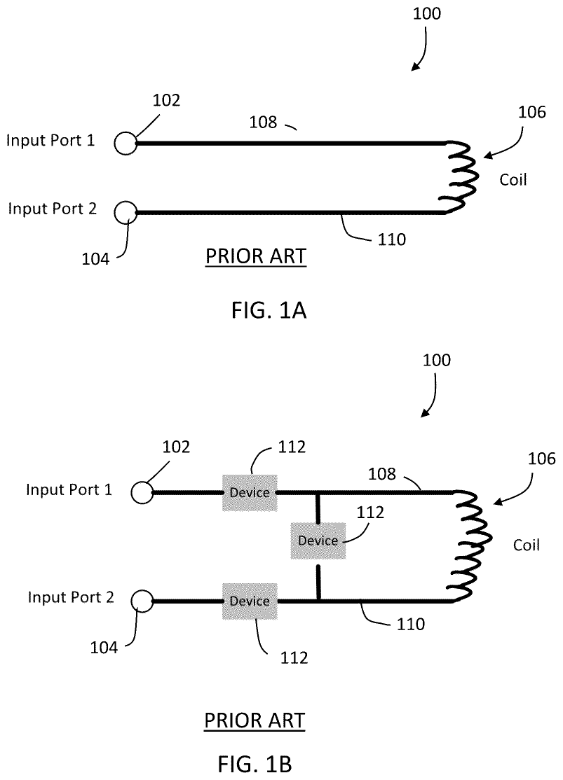

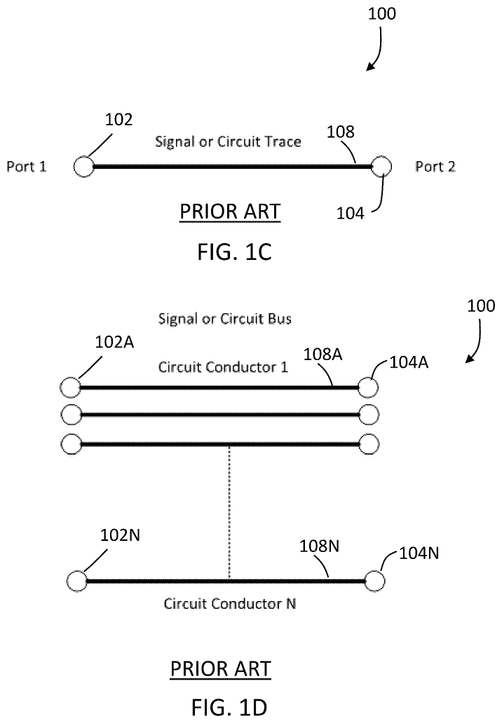

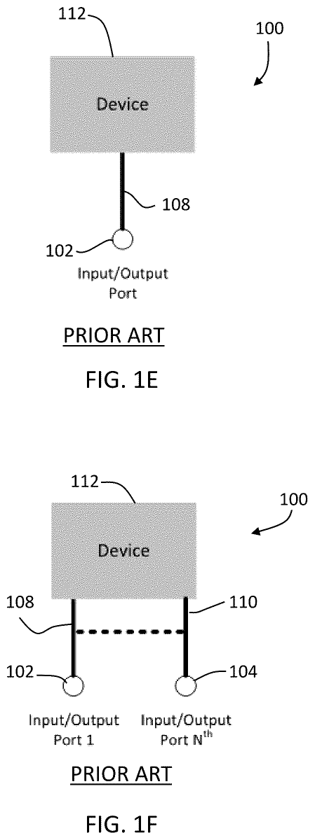

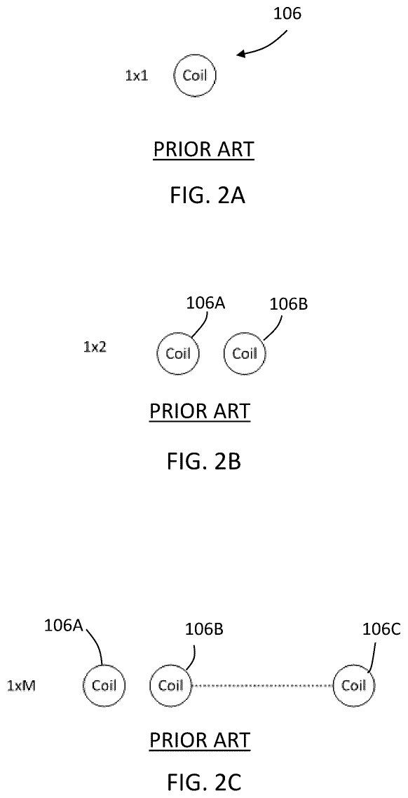

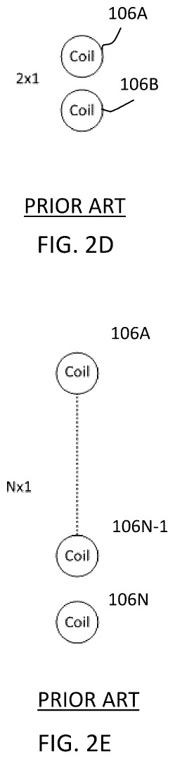

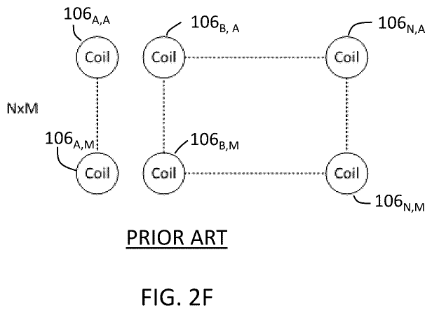

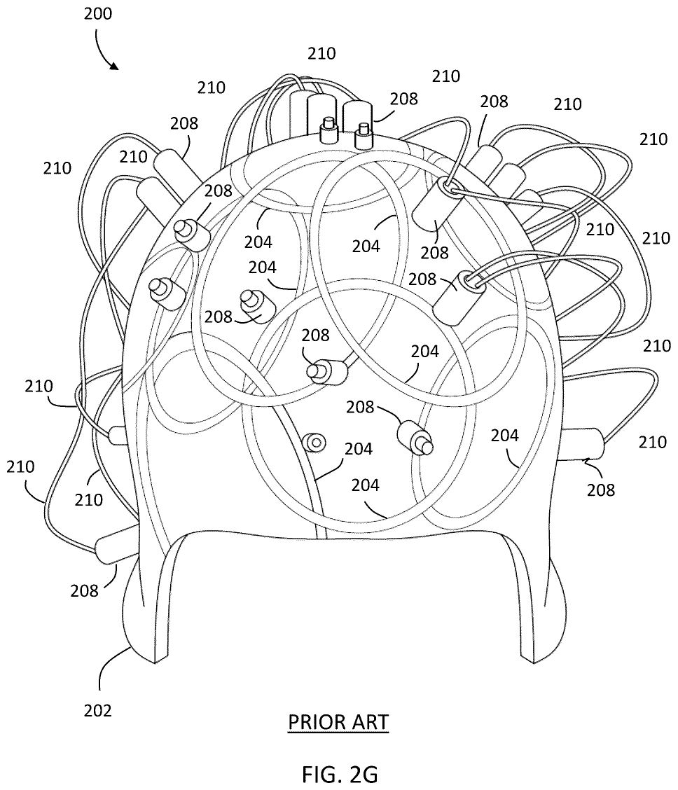

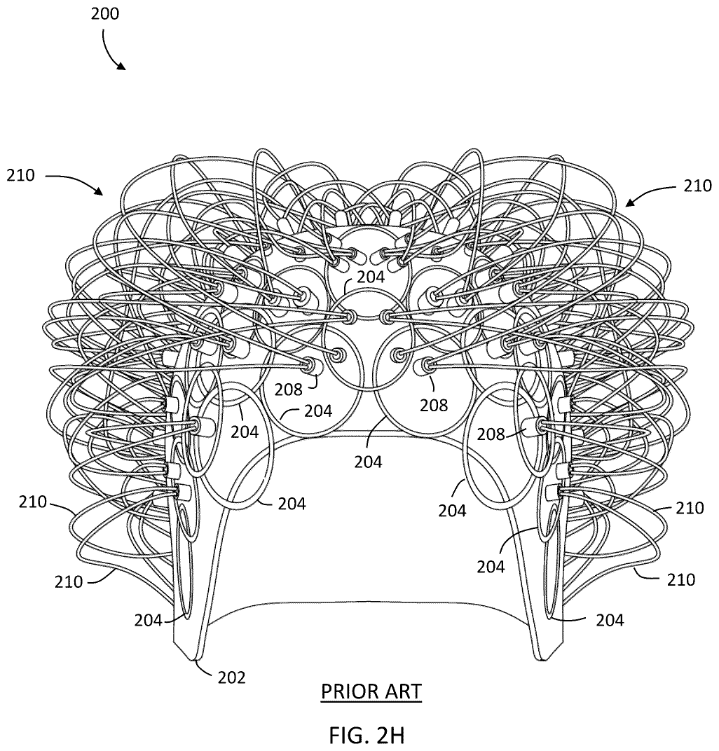

Referring now to FIGS. 1A-1F illustrate embodiments of prior art circuits 100, such as the type of circuits that may be used on an electrical or electronic system. An MRI device 200 (FIG. 2G, 2H) is illustrated for example. It should be appreciated that while embodiments herein refer to MRI systems, the teachings discussed herein may be applied to other systems, such as but not limited to industrial, commercial, or consumer devices containing electrical or electronic devices or systems for example. In still further embodiments, the teachings may be applied to any device made by additive manufacturing methods that incorporate electrical shielding for noise/interference reduction. In still further embodiments, the teachings may be applied to any device made by additive manufacturing methods that require electrical shielding for noise/interference reduction. These circuits 100 may include ports 102, 104 that are connected with a component, such as a coil 106 for example, by conductive traces 108, 110. The ports, traces and coil may be coupled to a substrate, such as a printed circuit board for example. Other circuits may include electronic components or devices 112 (FIG. 1B), These devices 112 may include any known electrical component, such as but not limited to capacitors, resistors, transistors, analog or digital integrated circuits and the like for example.

The circuit 100 may be a single conductive trace 108 that extends between two ports 102, 104 (FIG. 1C.) The circuit 100 may also be comprised of a plurality of conductive traces 108A-108N that extend in parallel (a circuit bus) between a first set of ports 102A-102N and a second set of ports 104A-104N (FIG. 1D). In some instances, the circuit 100 may be comprised of a single port 102 that is connected by a single conductive trace 108 to an electrical component or device 112 (FIG. 1E). In still further instances, the circuit 100 may be comprised of a two or more ports 102, 104 that are connected by traces 108, 110 to devices 112 (FIG. 1F).

Referring now to FIG. 2A-FIG. 2F instances of prior art coils 106 or coil arrays are shown. The circuit may include a single coil 106 (FIG. 2A) or a plurality of coils 106A, 106B in a 1×2 arrangement (FIG. 2B). In other instances the coils 106A-106M may be arranged in a 1×M array (FIG. 2C).

Other instances of coils 106 may be arranged in a 2×1 configuration with coils 106A, 106B (FIG. 2D). In still further instances the coils 106 may be arranged in an N×1 configures with coils 106A-106N (FIG. 2E). Finally, in still another example instance, the coils 106_{N,M} may be arranged in an N×M configuration (FIG. 2F).

Arrays and multi-device configurations of coils, antennas, high-speed signal circuits, busses, or other electronic devices may be used in a variety of applications. These applications include, but are not limited to computer systems, electrical and electronic based systems or devices, printed circuit board implementations, printed electronic implementations based on 3D printing systems and/or tools, mobile and satellite communications, Wi-Fi, radar, EW (Electronic Warfare), automotive radar systems and other autonomous vehicles, implementation of array and phased array antennas, magnetic resonance imaging (MRI), NMR coil assemblies as well as numerous other devices where complex electric, radio-frequency, and magnetic fields are generated to produce or receive desired transmission.

Generally, one or more high-speed signals and busses, complex antenna and coil system implementations seek to reduce or minimize undesirable effects due to adjacent or coupled fields as well as other interference mechanisms. This is especially the case in high-speed signal buses, multi-array configurations such as phased array antennas and multi-coils systems where buses, antennas and coils are formed as networks in a prescribed geometrically pattern or structure. In these cases, it is desired to ensure that intended signal integrity and/or field distributions are not impacted, distorted, or perturbed by signals or electrical currents, applied, or received, that transfer across the one or more elements (e.g. input/outport ports) of the given signal endpoints, antenna, antenna array, coil, or multi-coil configuration. As a further example, within electrical or electronic systems or devices, it is desirable to reduce or minimize noise and interference from either or both external and internally coupled sources that may otherwise negatively interact and impact such device signals in order to achieve reliable device operation and conformance to required electrical specifications of the device.

To mitigate these effects, typically prior art shielded cables are utilized to provide for antenna or coil input/output port interconnections to driver or receiver electronic devices and systems. In the case of parallel busses or other high-speed circuits, careful circuit design including impedance matching and ground planes are utilized as part of the circuit board implementation. In other prior art cases complete metallic ground enclosing structures are used to encapsulate underlying electronic components, circuitry, and signal conductors. Referring now to FIGS. 2G and 2H, an example is shown of an embodiment of a prior art MRI device 200 having a frame 202, such as a helmet for example. Disposed within or on the frame 202 are coils 204 arranged in an array. Each of the coils 204 is connected to a port 208. Each of the ports 208 is then connected in a predetermined manner to interconnect the coils and allow the coils to be energized. The interconnections are typically shield cables 210 that may be difficult to handle. Further, as shown in FIG. 2H, these connections are complex and difficult to assemble due to the number of coils coupled to the frame 202. It should be appreciated that this may result in misconnected coils that are difficult to troubleshoot and correct.

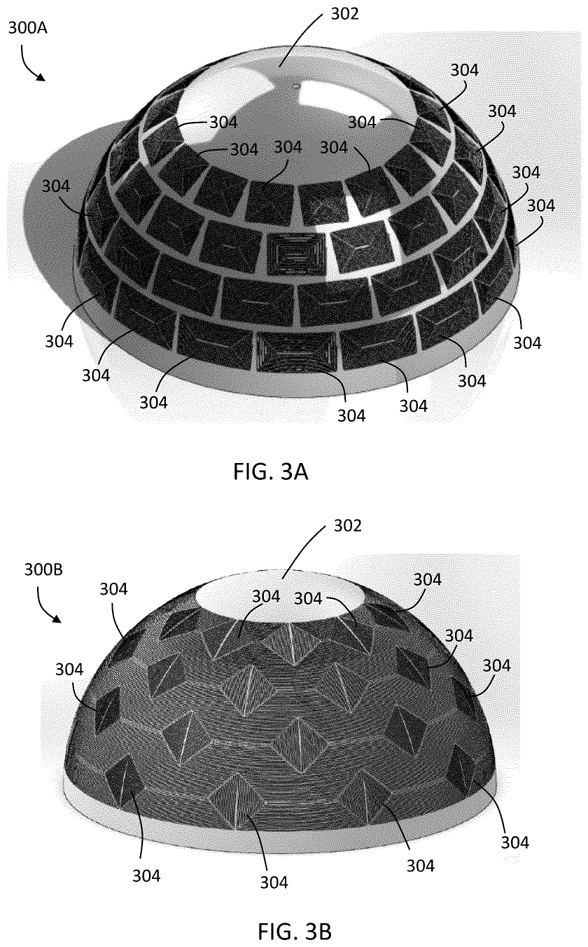

Embodiments herein provide for methods of using additive manufacturing processes or deposition processes to fabricate devices or assemblies that reduce electrical noise and magnetic field interference generated by one or more electrical, electronic circuits, components, signals, parallel busses, antenna, antenna arrays, and coil/multi-coil system components or elements. Referring now to FIGS. 3A and 3B an embodiment is shown of a multi-coil/antenna/array system 300A, 300B that may be fabricated using methods described herein.

In this embodiment, the system 300A, 300B includes a base structure 302 that is fabricated using additive manufacturing systems as described herein. In an embodiment, the base structure 302 is fabricated by depositing a material on a build platform. The based structure 302 may be made from a material that allows for the transmission of RF signals and magnetic fields, or may be composed of materials that have topology optimized dielectric constants and additive manufactured structures or geometries (including optimized lattice or infill patterns to manipulate the dielectric properties of the materials) for the purposes of improving or optimizing the field propagation characteristics for example. In the illustrated embodiment, the base structure has a semi-spherical shape. The internal portions of the base structure may include a hollow space (not shown) such as to receive a sample to be analyzed for example. In the illustrated embodiment a plurality or array of coils 304 are fabricated on, or integrally formed with, the base structure 302. The coils 304 may be identical or different sizes depending on the desired results of the application. In an embodiment, the array of coils 304 extends about the circumference or perimeter of the base structure 302.

The coils 304 may be made from a conductive trace material that is deposited on the base structure 302. As discussed in more detail herein the coils 304 may be embedded beneath additional layers that provide shielding and insulation functions to the system 300A, 300B. In the embodiment of FIG. 3A, the connections between coils 304 may be on a separate layer than the coils 304. In the embodiment of FIG. 3B, connections between the coils 304 may be integrally formed on the layer that the coils 304 are fabricated.

It should be appreciated that coils 304 or antennas that are fabricated on the base structure 302 that are illustrated in FIGS. 3A, 3B are for example purposes only and other shapes, sizes, or configurations of coils, antennas, signal circuits and the like may be fabricated using the additive manufacturing methods described herein without deviating from the teachings provided herein.

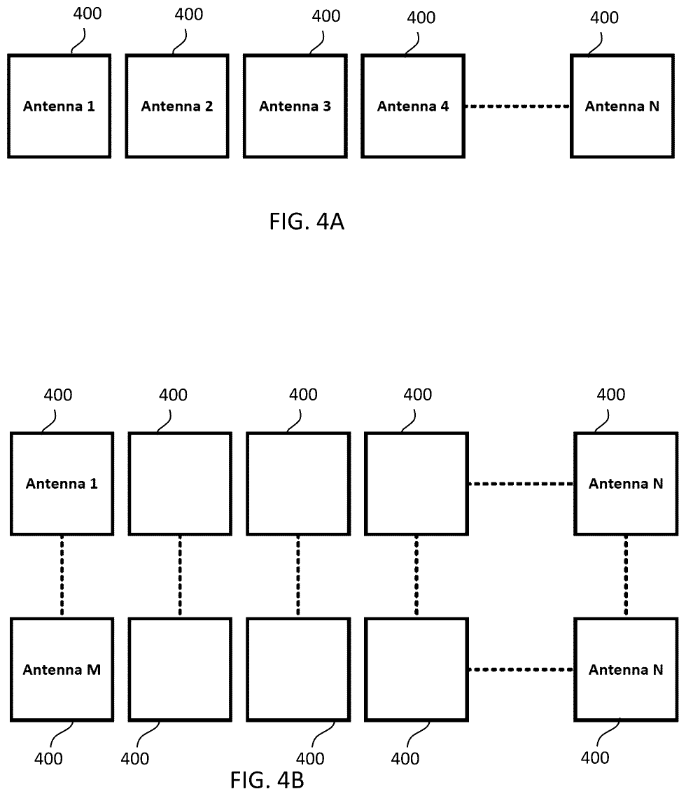

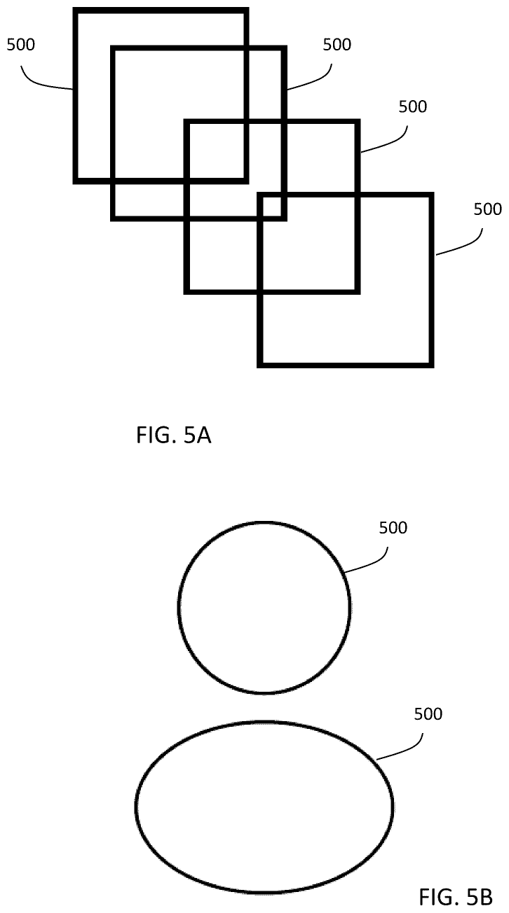

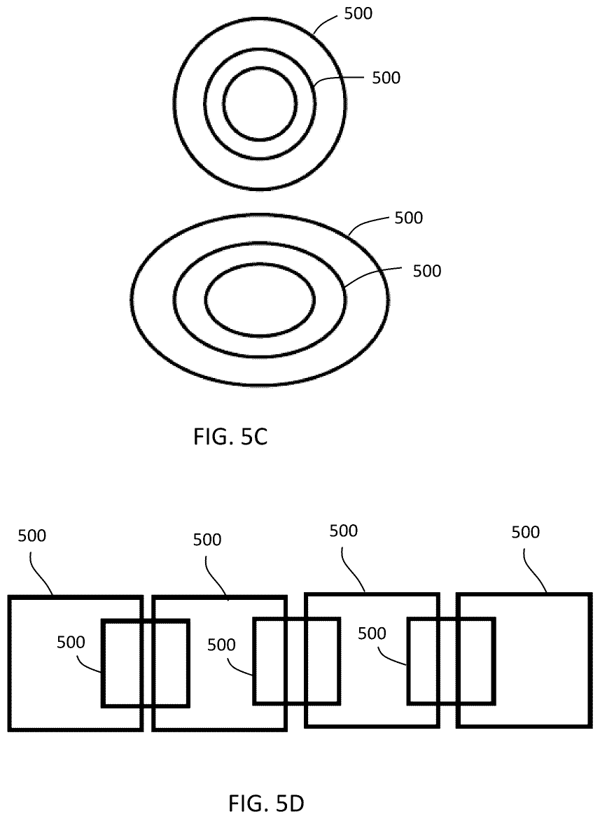

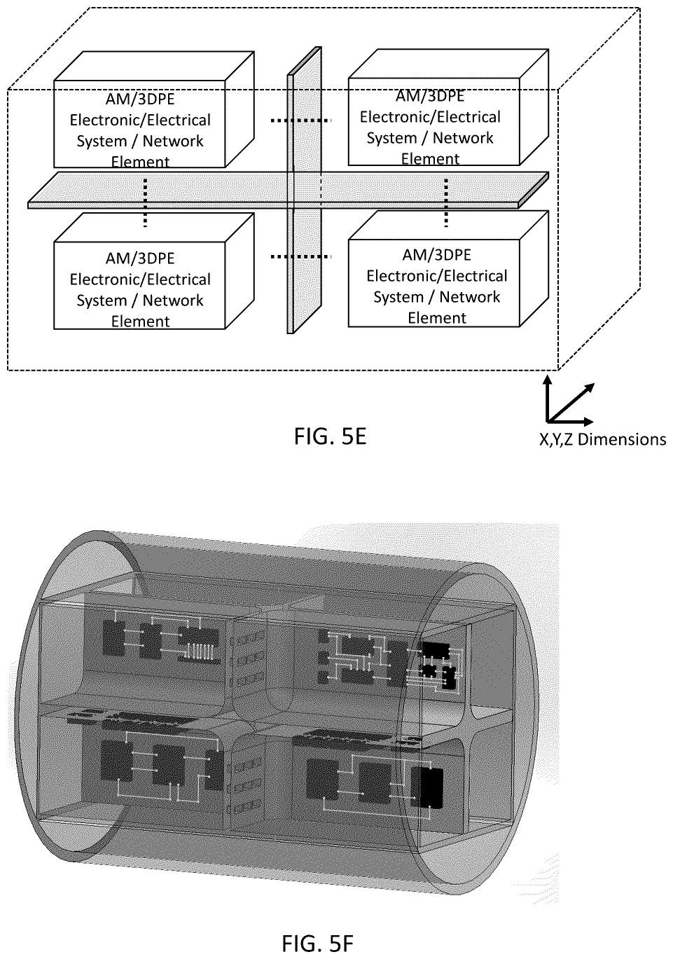

For example, the coils, antennas 400, signal circuits and electronic devices may be arranged sequentially as shown in FIG. 4A. In other embodiments, the coils, antennas 400, signal circuits and electronic devices may be arranged in an N×M matrix as shown in FIG. 4B. In some embodiments, the coils, antennas 500, signal circuits and electronic devices may be arranged in a square, rectangular or other polygonal shape as shown in FIG. 5A. In still further embodiments, the coils, antennas 500, signal circuits and electronic devices may have round, curved, oval, elliptical shapes as shown in FIG. 5B. The coils, antennas, signal circuits and electronic devices may overlap one or more adjacent circuits as shown in FIG. 5A or may be separate as shown in FIG. 5B.

In some embodiments, the coils, antennas 500, signal circuits and electronic devices may be arranged concentrically as shown in FIG. 5D. In still further embodiments, adjacent coils, antennas 500, signal circuits and electronic devices may overlap as is shown in FIG. 5D.

In some embodiments, additive manufactured electronic systems using 3D printed electronic methods may be utilized. Example representations illustrated in FIGS. 5E and 5F depict an additive manufactured 3-dimensional geometry where electrical, electronic, coils or other devices are fabricated on the surface of or within at least some portions of the 3-dimensional geometry as one or more elements that exist in 3-dimensional space. It should be appreciated that the methods described herein may be used in such manufacturing methods and processes to provide an efficient method for reducing noise and interference of the electronic or electrical systems and networks as isolation between elements and within the structures of each element.

As a further embodiment of FIG. 5F. an implementation method may incorporate the use of component voxel methods for 3-dimensional additive manufacturing of 3-dimensional printed electronic devices, assemblies or systems. The methods described herein may be used to provide for interference and noise reduction for one or more component voxels as further described in pending application #.

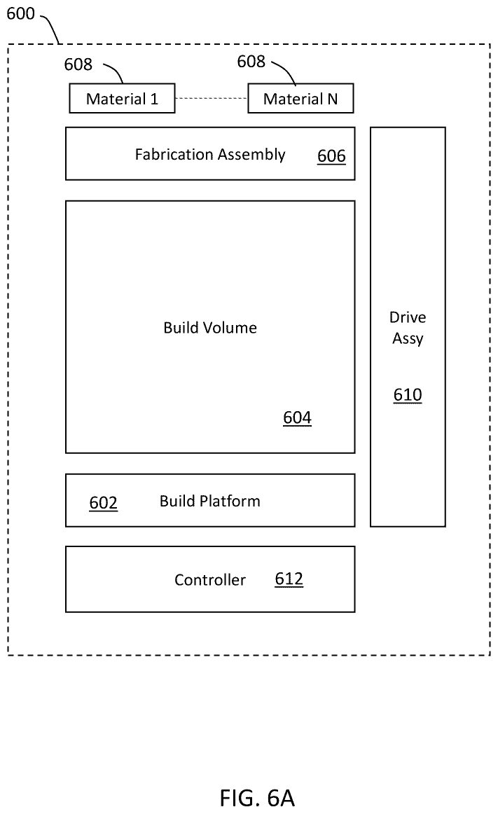

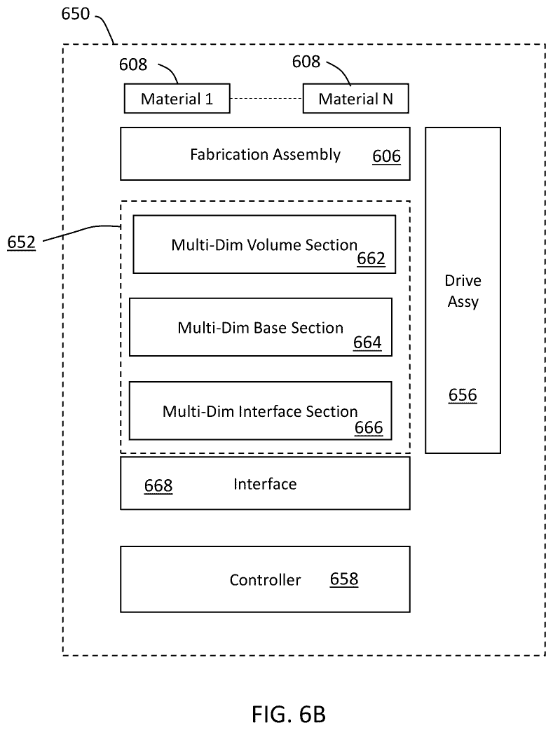

As discussed, the methods provided herein use an additive manufacturing process to fabricate the devices that include the coils, antennas, signal circuits and electronic devices. Two types of additive manufacturing systems are shown in FIG. 6A and FIG. 6B. It should be appreciated that the two systems shown in FIG. 6A and FIG. 6B are for example purposes only and other additive manufacturing systems may be used without deviating from the teachings provided herein.

FIG. 6A illustrates the base components of an additive manufacturing system 600. In this embodiment, the system 600 includes a build platform 602 which supports the device being fabricated in a build volume 604. The system includes a fabrication assembly 606 that includes tools, such as an extruder for example, that deposit material or perform operations on previously deposited material. The fabrication assembly 606 receives one or more materials 608 that are deposited in the build volume 604 during operation. It should be appreciated that a number of different materials may be used in operation, such as conductive and nonconductive materials for example. A drive assembly 610 is operably coupled to the build platform and the fabrication assembly to move the components during the fabrication of the device. For example, the drive assembly 610 may cause the tools of fabrication assembly 606 to move in an X, Y plane (e.g. a plane extending perpendicular to the plane of the sheet that includes FIG. 6A) and to move the build platform 602 in a Z-direction (e.g. a direction along the length of the sheet that includes FIG. 6A). One or more controllers 612 are operably connected to the drive assembly, build platform, fabrications assembly and material dispensers to coordinate operation of the system 600. In some embodiments, the controller 612 may execute some or all of the methods described herein.

In some embodiments, the methods herein may be performed using multiple discrete additive manufacturing systems that cooperate to fabricate the target object. For example, in an embodiment, a metal additive manufacturing system, for example, in combination to with a second additive manufacturing system that fabricates and/or places the electronic components. In other embodiments, the additive manufacturing system is provided that functions on multiple axis (e.g. 5-axis) that is configured to deposit or print multiple materials, including metal, composite and polymer materials for example. The system may further include functionality and assemblies to pick and place components that are integrated into the target object.

Referring to FIG. 6B, an additive manufacturing system 650 is provided that includes a multi-dimensional build platform 652, a fabrication assembly 654, a drive assembly 656 and a controller 658. In an embodiment the system 650 is the same as that described in commonly owned and co-pending U.S. patent application Ser. No. 17/574,326 filed on Jan. 12, 2022, the contents of which are incorporated herein by reference The components of the system 650 may be coupled by a frame or enclosure. The multi-dimensional build platform 652 is positioned in a three-dimensional space and material may be deposited or added to the multi-dimensional build platform 652 to form the target or fabricated object. It should be appreciated that while embodiments herein may refer to three-dimensional space, it should be appreciated that the systems and methods described herein may be applied to a two-dimensional space without deviating from the teachings contained herein.

In an embodiment, the three-dimensional space may be defined in terms of an x-axis, a y-axis and a z-axis as described herein with respect to FIG. 6A (e.g. a 3-axis system). In other embodiments, such as the multi-dimensional build platform 652 shown in FIG. 6B, the 3D space may further be defined in terms of a roll angle, pitch angle, or yaw angle (e.g. a 4, 5 or 6-axis system). The multi-dimensional build platform 652 may also be positioned in 3D space and functional tool operations may be performed to the multi-dimensional build platform 652 to fabricate additional features and structures (mechanical, electromechanical, electronic components, devices, and systems, conductive circuitry, microfluidic, as non-limiting embodiments) to the target or fabricated object in the exemplary embodiment, the multi-dimensional build platform 652 defines one or more surfaces that extend in three-dimensional space. The multi-dimensional build platform 652, the fabrication assembly 654, or a combination thereof may be moved in three or more degrees of freedom. In an embodiment, the system can operate with any combination of six-degrees of freedom (X, Y, Z, Roll, Pitch, Yaw) as illustrated and inclusive of nine-degrees of freedom. In an embodiment the multi-dimensional build platform 652 may also be positioned to operate in a horizontal position.

The fabrication assembly 654 may include any suitable additive manufacturing material handling unit, such as but not limited to an extruder for example. The type of material depositing device used in fabrication assembly 654 used will depend on the type of additive manufacturing system used, such as fused filament fabrication (FFF), fused deposition modeling (FDM), stereolithography (SLA), material or binder jetting, selective laser sintering (SLS), digital light projector (DLP), or direct metal laser sintering (DMLS) and other powder bed fusion methods. It should be appreciated that the multi-dimensional build platform 652 may be used in any known additive manufacturing system that is capable of operating in multiple dimensions (e.g., three or more degrees of freedom). The assembly may further include tools or systems used for fabricating the target object. These tools or systems may include but are not limited to: ink deposition systems (including nano-scale inks), aerosol jet systems, paste deposition and dispensing systems, optical or laser alignment tools, curing tools, sintering tools, surface energy tools, milling tools, cutting tools, pick and place tools, and laser ablation systems for example. It should be appreciated that while embodiments herein may refer to the deposition of plastic or powdered-metal materials, this is for example purposes and the claims should not be so limited. In other embodiments, the systems and methods disclosed herein may be applied to inorganic and/or organic materials including materials (such as biomolecular or biomaterials) used in additive manufacturing processes that are sometimes referred to as “bioprinting.”

It should be appreciated that the fabrication assembly 654 may include both additive manufacturing and subtractive manufacturing functionality to form the target object. For example, the fabrication assembly 654 may generate an initial form of the target object using additive manufacturing, then remove material (e.g., using a drill or end-mill) such as to form a pocket, and then place a sub-assembly (e.g., a circuit or a sensor) into the pocket using a pick and place tool.

In an embodiment, the geometry, characteristics, properties and functionality of the object to be fabricated (i.e., the target object) may be defined based on a specification and associated set of requirements as input typically defined by a Computer Aided Design (CAD) system or some other generative specification such as a 3D scanner or camera system or combinations of such tools and design systems. The output of such systems the object to be fabricated is typically described in surface or volumetric formats including but not limited to mesh, boundary-representations, volumetric, formats based on constructive geometry methods and operations, and point-clouds, any of which represent the target object.

In an embodiment, the drive assembly 656 is an articulated robotic arm that moves the fabrication assembly 654 relative to the multi-dimensional build platform 652. It should be appreciated that in other embodiments, other types of device assemblies may be used. For example, one or more robotic arms or actuators can coordinate multiple drive assembly units 656 and multi-dimensional build platforms 652 in an integrated cluster or network of fabrication systems operating in a coordinated manner. The fabrication system network comprising multiple multi-dimensional build platforms 652 (where each multi-dimensional build platform, in the network of multiple multi-dimensional build platforms, supports fabrication of a complete or partial target object assembly, sub-assembly or component) providing the advantage of further increases in production velocity or complexity of the target object and reduced manufacturing or product costs. The robotic arm and multiple multi-dimensional build platform fabrication system are for example purposes and the claims should not be so limited.

In an embodiment, the multi-dimensional build platform 652 includes three sections that may be formed as separate components that are coupled together, or integrally formed, depending on an embodiment as further described within the application disclosure. These sections include a build volume section 662, a base section 664 and an attachment interface section 666.

In contrast to the planar build plate (also known as build-plate, hotbed, printer bed, or print surface) such as that which may be used in the system 600, a multi-dimensional build platform 652 may take on a plurality of geometries including both linear and non-linear or curved surfaces or volumes across multiple dimensional axes. The build platform supports the use of complex material deposition or extruders, sintering, lasers, tools, actuators, additive manufacturing system platform movements (such as rotational, tilt, pitch, yaw, roll, X-Y-Z, spherical, Euler angles, and other axes of movement and their respective representations or transformations) within the capabilities supported by a multi-axis additive manufacturing system. A multi-axis additive manufacturing system supports tools and tool path orientations in arbitrary 3D space. It should be appreciated that prior art additive manufacturing systems include tools that operate normal to a Z-axis relative to a planar build plate.

The build volume section 662 comprises the build platform surface or volume region where additive fabrication processing occurs in terms of sequential/multiple material deposition, functional and structural fabrication operations. In this section, additive manufacturing system tools are utilized for fabricating some target object in accordance with the tools and their respective operational characteristics within the additive manufacturing system. As used herein the multi-dimensional nature of the build volume section 662 is an intelligent and reconfigurable system that may be in dimensions that include physical space, temporal, energy, information, physical parameters, or a combination thereof that can vary in time in a fully dynamic manner.

Below the build volume section 662, the second section is provided that includes a base section 664. The base section 664 is not included in the fabrication process, but rather is utilized to provide functionality support of the implementation of the given multi-dimensional build platform 652. The base section 664 may be configured in a variety of categories, such as but not limited to square, rectangular and circular base sections. The third section, located adjacent to or underneath the base section 664, is an attachment interface section 666 that secures the first two sections 662, 664 of the multi-dimensional build platform 652 to the additive manufacturing system 650 platform interface 668. The base section 664 and attachment interface section 666 may vary in implementation in accordance with the configuration of the build volume section 662.

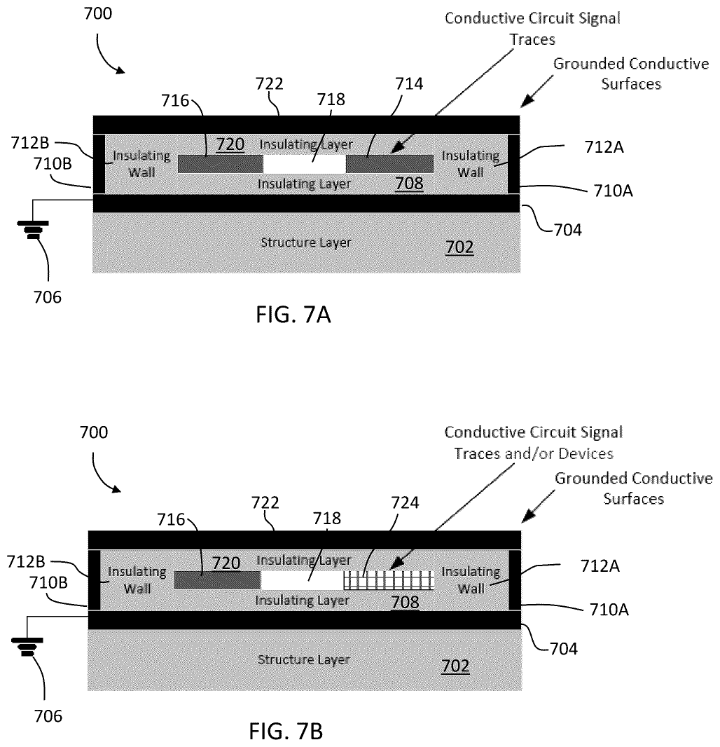

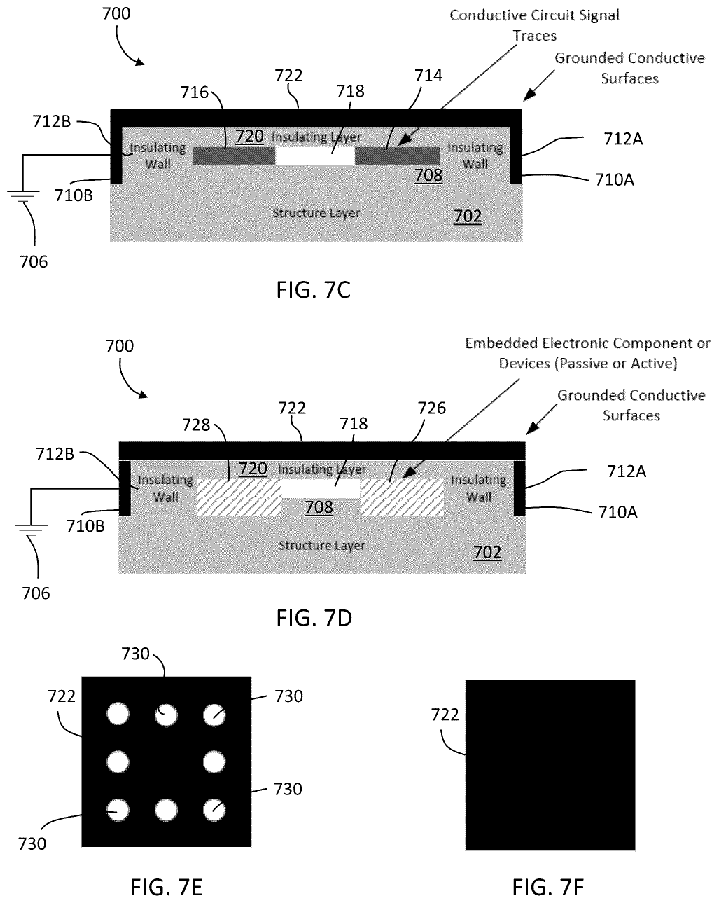

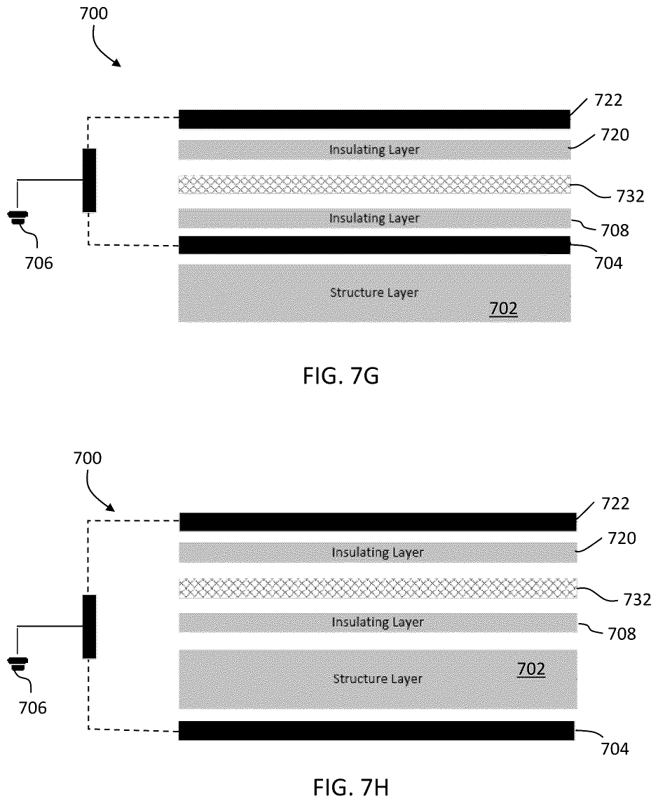

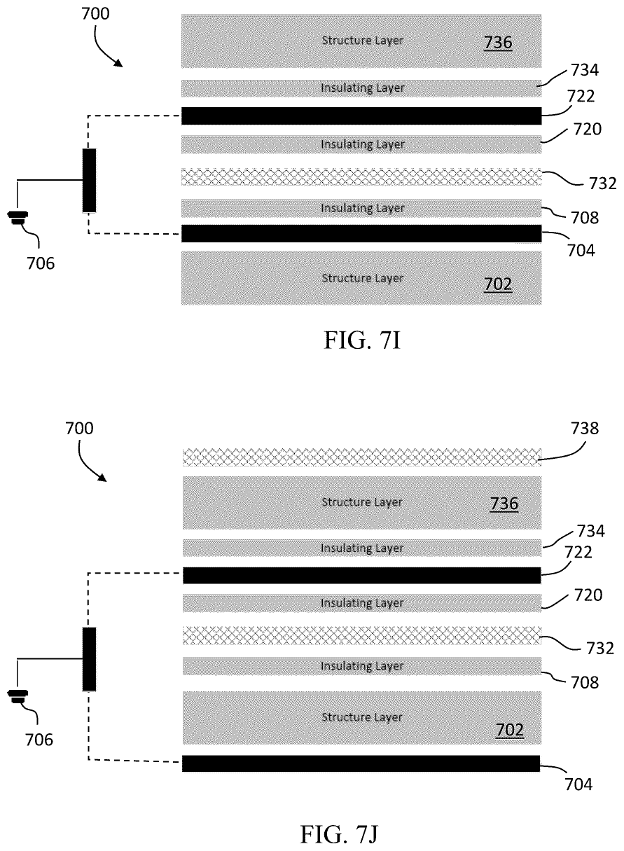

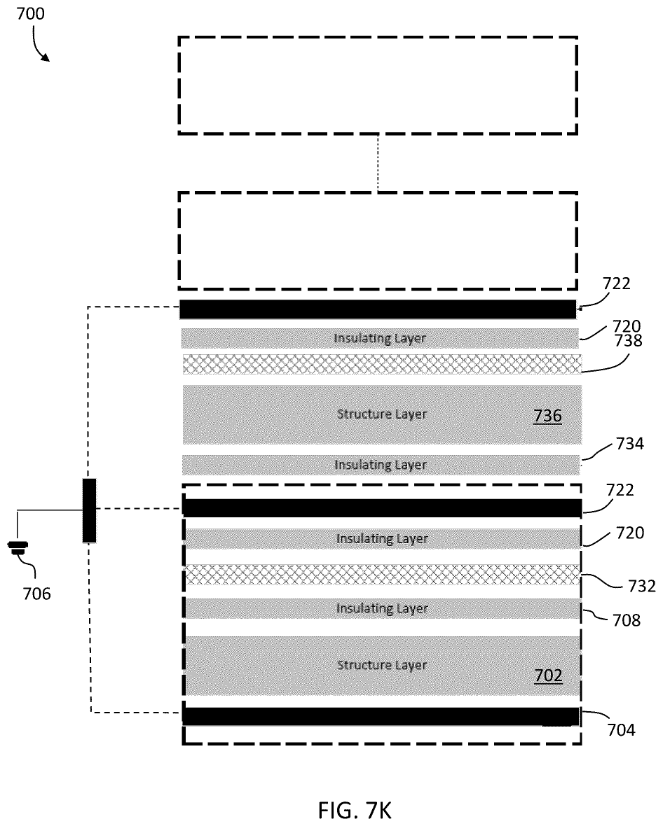

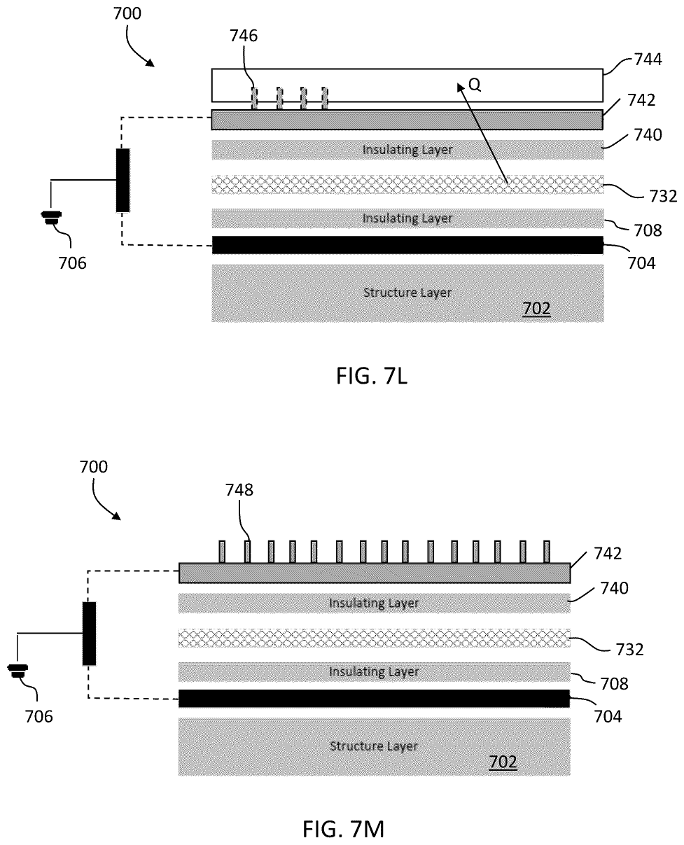

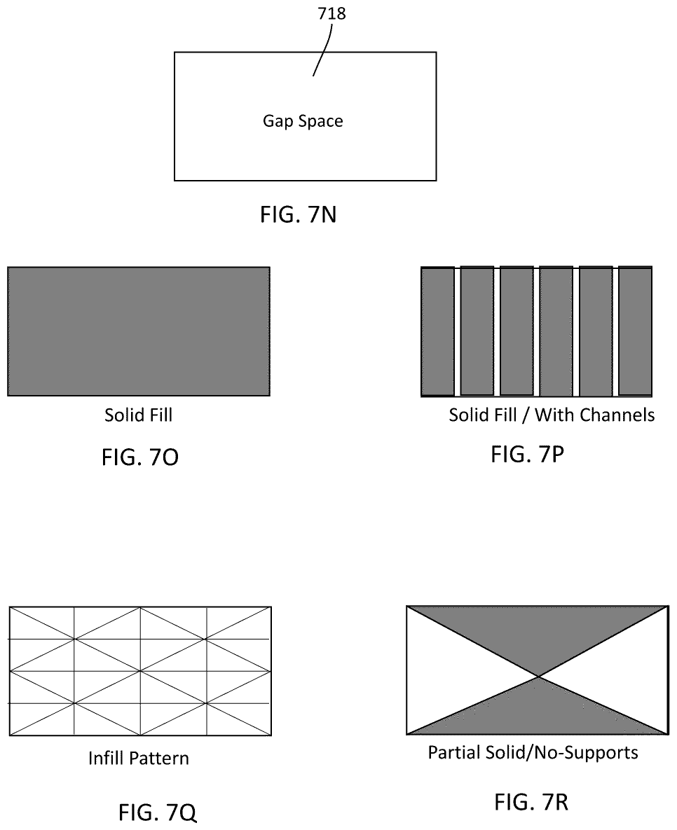

Referring now to FIG. 7A-7K embodiments are shown of structures with integrated circuits and electrical devices/components that were manufactured in an additive manufacturing system in accordance with the methods described herein. The additive manufacturing system may be the systems 600, 650 shown in FIG. 6A, 6B for example, or any suitable additive manufacturing system configured for depositing materials in a desired shape. FIG. 7A shows a device or system 700 having a base structural 702, such as the dome or semi-spherical structure 302 of FIG. 3A, 3B for example. The device 700 is fabricated in layers by the additive manufacturing system to define an integrated component. It should be appreciated that while some embodiments herein illustrated the base structure as being a dome-shape, this is for illustrative purposes and the claims should not be so limited.

The view shown in FIG. 7A-7K are cross-sectional views of the device and the system 700 may have a three-dimensional shape in the direction extending into and out of the plane of the drawing. In other words, the device 700 may not be planar or flat in the direction perpendicular to the page and may have a curved shape in this direction. Further, while embodiments herein describe the fabrication of the device 700 as being performed in a particular direction, such as in a direction extending from the bottom of the page to the top of the page in the FIGs., this is for example purposes and in other embodiments, the additive manufacturing system may deposit material in a different direction, or along 2, 3, 4 or more axes.

Onto at least a portion of the base structure 702 is deposited a first grounding layer 704 that is connected to ground 706. Over the ground layer 704 is a an insulation layer 708 that is enclosed by grounded conductive surfaces 710A, 710B. The grounded conductive surfaces 710A, 710B are electrically coupled to the ground layer 704. The insulation layer 708 is made from a material that electrically isolates the grounding layer 704 and grounded conductive surfaces 710A, 710B from adjacent electrical circuits and devices as discussed herein.

Next, a layer is formed that includes the grounded conductive surfaces 710A, 710B and insulation walls 712A, 712B. The insulation walls 712A, 712B define an area in which conductive circuit signal traces 714, 716 are deposited with an gap 718 disposed therebetween. The gap 718 may be any of solid non-conductive material, an infill pattern, or partial-solid gap structure as shown in FIGS. 7N-7R. In an embodiment the gap structure may also be utilized for implementing any given insulating wall or layer region as referenced herein. In an embodiment, one or more gap structure geometries includes one or more channels for thermal heat dissipation. It should be appreciated that one or more variants of FIG. 7N-7R include combinations of geometries, channels, solid, in-fill, and partial solid implementations. The conductive circuit signal traces 714, 716 are made from an electrically conductive material. In an embodiment, the conductive circuit signal traces 714, 716 form part of the coil or antenna circuit 304 of FIG. 3A, 3B.

The next layer (in a direction extending normal to the surface of the base structure 702) is an insulation layer 720. The insulation layer 720 may be made from the same material as insulating layer 708 and insulating walls 712A, 712B. The insulation layer 720 encloses the conductive circuit signal traces 714, 716 and the gap 718 to electrically isolate the circuits from adjacent layers. Finally, in the embodiment of FIG. 7A, an outer grounded conductive layer 722 is deposited over the insulation layer 720. It should be appreciated that the grounded conductive layers 704, 710A, 710B, 722 form a Faraday cage about the conductive circuit signal traces 714, 716. As used herein a Faraday cage is an enclosure that is used to block or inhibit electromagnetic fields.

The embodiment of FIG. 7B, is similar to FIG. 7A except that instead of depositing a conductive circuit signal trace 714, an electrical device 724 may be fabricated adjacent to the conductive circuit signal trace 716. It should be appreciated that the electrical device 724 may be any suitable electrical component, such as but not limited to: resistor/capacitor, inductors/coils, antennas, transistors, (either as additive manufacturing fabricated or conventional passive/active components) semiconductors, and integrated circuit (e.g. memory, microprocessors/controllers, field programmable gate arrays) for example. The electrical device 724 may further be an embedded electrical system, machines, and/or components, such as but not limited to actuators, steppers, motors, and pumps for example. In still further embodiments, the electrical device 724 may be one or more sensors that contain chemical structures (e.g. electro-chemical, electro-mechanical, etc). In still further embodiments, the additive manufacturing could be used to fabricate a structure, a motor is the moved into place (e.g. pick and place), then additional material is added around the structure and/or motor using additive manufacturing to reduce EMI and forming a shielding unit around the motor.

The embodiment of FIG. 7C is similar to FIG. 7A except that the grounding layer 704 is omitted. In this embodiment, the insulation layer 708 may be made from the same material as the base structure 702. In other embodiments, the insulation layer 708 and the base structure 702 may be made from different materials with the insulation layer 708 having electrical insulation properties.

The embodiment of FIG. 7D is similar to FIG. 7C, except that the conductive circuit signal traces 714, 716 are replaced with embedded electronic components or devices 726, 728. It should be appreciated that the devices 726, 728 may be active or passive electronic components. In some embodiments, the devices 726, 728 may be fabricated by the additive manufacturing system, or may be separately fabricated and inserted, such as with a pick and place system for example. In an embodiment, the devices 726, 728 are positioned directly on top of the surface of the base structure 702 with the insulation layer 708 being disposed between the devices 726, 728. In an embodiment the devices 726, 728 maybe electro-mechanical components such as actuators, pumps, motors, sensors, and other devices that comprise a combination of different elements including electronic, electrical, mechanical, or chemical materials and characteristics.

It should be appreciated that the grounded conductive surface 722 may include openings to allow for heat transfer. In an embodiment, one or more gap structure geometries includes one or more channels for thermal heat dissipation. As shown in FIG. 7E, the layer 722 may include a plurality of openings or holes 730 to increase the heat transfer from the circuits 714, 716, the device 724, or the components 726, 728. In other embodiments, the layer 722 may be a solid layer as is shown in FIG. 7F.

In still another embodiment, shown in FIG. 7G, the device 700 may be fabricated with different number, orientation, shape and sizes of layers. In this embodiment, a grounding layer 704 extends across the surface of the based structure 702 with an insulation layer 708 deposited opposite the base structure 702. Another layer 732 that defines a signal, circuit, bus, or device layer is formed on top of the insulation layer 708. Over the signal, circuit, bus, or device layer 732 is another insulation layer 720 is deposited. Finally, an outer grounded conductive layer 722 is formed over the insulation layer 720. Since the ground layers 704, 722 are not directly in electrical contact, these layers 704, 722 may be connected to ground 706 external to the layers.

The embodiment of FIG. 7H is similar to FIG. 7G except that the structure layer 702 is formed on grounded conductive layer 704. The insulation layer 708 is deposited between the structure layer 702 and the signal, circuit, bus, or device layer 732 to electrically isolate the signal, circuit, bus, or device layer 732 from the structure layer.

Referring to FIG. 7I, an embodiment is shown where the device has multiple additional layers and the grounding layers 702, 722 may be embedded below the outer surface of the device 700. This embodiment is similar to FIG. 7G with the addition of a third insulation layer 734 disposed on the second conductive grounded layer 722. In an embodiment, a second structure layer 736 may be deposited on the third insulation layer 734.

In FIG. 7J, an embodiment is shown of a device 700 having the third insulation layer 734 and second structure layer 736. This embodiment, like that of FIG. 7H arranges the first structure layer 704 between the first conductive grounded layer 704 and the first insulation layer 708. Further, in this embodiment, the device 700 further includes a second signal, circuit, bus, or device layer 738 on the outer surface of the second structure layer 736.

Finally, FIG. 7K shows device 700 that combines the embodiments of FIGS. 7A-7J to define a multi-layer shielded circuit and device structure. In an embodiment, FIGS. 7A-7J are illustrated in planar orientations, it should be noted that each layer may be in any non-planar orientation, or direction, such as a curved geometry and may exist anywhere within a 3-dimensional space. It should be further appreciated that the embodiments of FIGS. 7A-7K are examples and other combinations of shielded circuit and device layers may be fabricated without deviating from the teachings described herein.

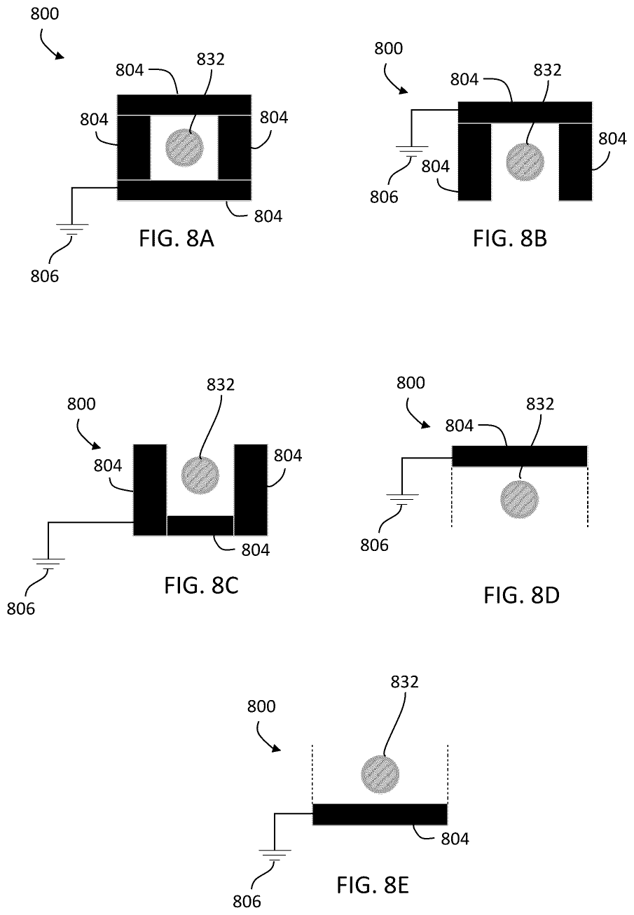

Referring now to FIGS. 8A-8E, different embodiments of shielded structure arrangements 800 are shown that may be fabricated using the additive manufacturing methods described herein to combine grounded conductive surfaces 805 to shield signals, circuits, buses or devices 832. Similar to the embodiments of FIGS. 7A-7K, the illustrations of FIGS. 8A-8E are a cross-section view of the arrangements 800 and the shape of the arrangement 800 in a direction perpendicular to the page of FIGS. 8A-8E may be curved or vary and is not necessarily a planar structure. Each of the arrangements 800 includes one or more conductive grounded layers 804 that are electrically connected to each other and to ground 806. It should be appreciated that the number, size, shape, and orientation of the conductive grounded layers 804 may be varied to provide a desired shielding performance.

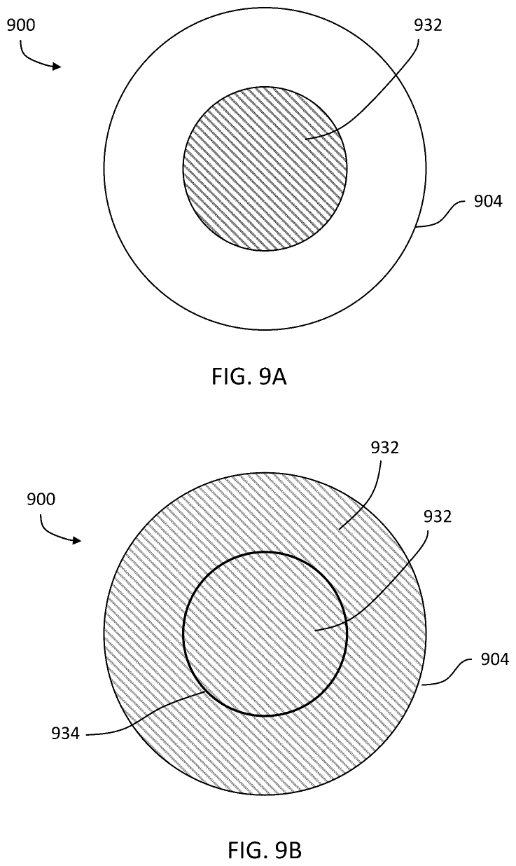

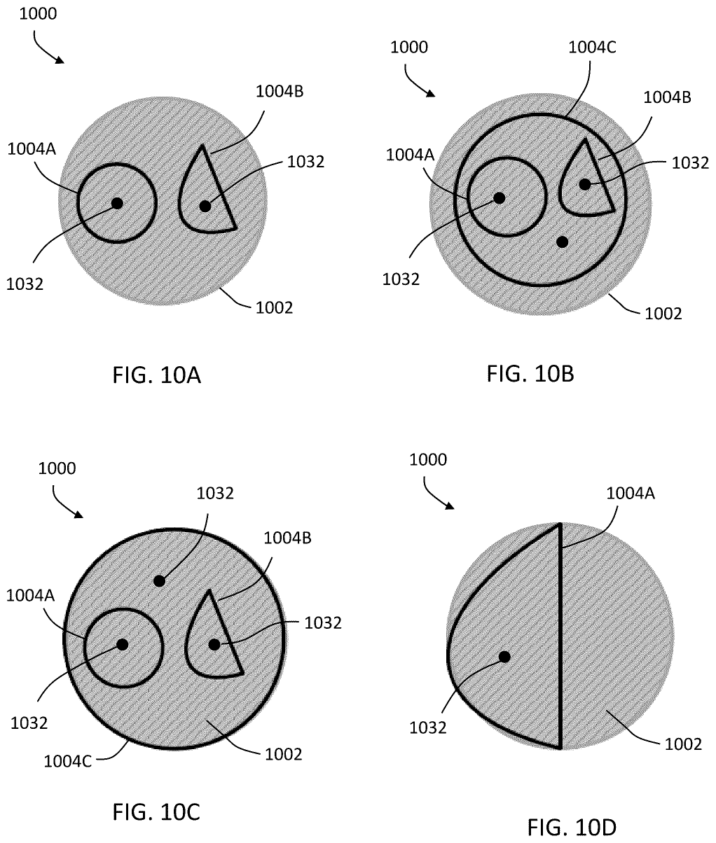

Referring now to FIG. 9A, 9B, embodiments are shown of a device 900 having one or more conductive grounded layers 904. In these embodiments, the conductive grounded layers 904 encapsulate or encase the shield signals, circuits, buses or devices 932. The conductive grounded layers 904 may have a circular cross section, an arbitrary curved cross-section, an elliptical cross-section, a polygonal cross-section, a cross-section having a combination of planes and curves, or a combination of the forgoing, such as the conductive grounded layers 1004 of devices 1000 shown in FIGS. 10A-10D.

The device 900 may include multiple layers of concentric conductive grounded layers 904 (FIG. 9B). In other embodiments, shown in FIGS. 10A-10D, one or more nonidentical or asymmetric shaped conductive ground layers 1004 may be disposed within a base structure 1002. In the embodiment of FIG. 10A, the base structure 1002 may include a first conductive grounded layer 1004A having a circular shape and a second conductive grounded layer 1004B having an asymmetric shape, where both of the conductive grounded layers 1004A, 1004B are embedded in the base structure 1002. It should be appreciated that one or more circuits or devices 1032 may be disposed within the conductive grounded layers 1004A, 1004B. In the embodiment of FIG. 10B, the conductive grounded layers 1004A, 1004B are embedded in the base structure 1002 with a third conductive grounded layer 1004C embedded within the base structure 1002 and disposed about the conductive grounded layers 1004A, 1004B. It should be appreciated that while the conductive grounded layer 1004C is shown as having a circular cross-section, in other embodiments, the conductive grounded layer 1004C may have a different shape, such as an oval, an ellipse, a polygon, or a multi-faceted shape for example.

In the embodiment of FIG. 10C, the conductive grounded layer 1004C is disposed on the outer surface of the base structure 1002 with the conductive grounded layers 1004A, 1004B being embedded within the base structure 1002. In FIG. 10D, an example is shown of a asymmetric conductive grounded layer 1004A having portions with on the surface and embedded within the base structure 1002. It should be appreciated that one or more circuits or devices 1032 may be disposed within the conductive grounded layer 1004C external to the conductive grounded layers 1004A, 1004B. It should further be appreciated that the embodiments of FIGS. 10A-10D are for example purposes and in other embodiments more or less conductive grounded layers having one or more different shapes, including three-dimensional geometries as described herein, may be provided.

As an embodiment, FIGS. 7A-10D illustrate representative fabrication methods for obfuscating the underlying design and operation of the object and its integral circuits and their function from efforts related to tampering and reverse engineering. That is, circuit and network structures depicted and any associated interconnections used for shielding and interference reduction can also be utilized as a method for blocking or hindering the use of external devices, such as probes, scanners, and other measuring or imaging equipment for example, for analyzing and/or determining the internal structure of an object and its internal structure. It should be appreciated that the embodiments of FIGS. 7A-10D are examples and the claims should not be so limited. In other embodiments, other configurations of layers, or combinations of the illustrated embodiments may be provided without deviating from the teachings herein.

In an embodiment, the obfuscation layers may include materials, such as but not limited to high atomic number materials (lead, tungsten, titanium, vandium) or aluminum with a mu-metal coating (nickel-iron alloy with high magnetic permeability) for example, to reduce the risk of the underlying circuits being inspected by an apparatus, such as a scanning electron microscope or X-ray tomography. In some embodiments, the obfuscation layer may include materials that inhibit disassembly, including destructive assembly of the object. This may include depositing materials such as pigmented potting material (e.g. thermosetting plastics, silicone rubber gels, and other lower glass-transition temperature compounds) on the electrical components. In still other embodiments, the obfuscation layer is an epoxy material with a filler that includes fine sand. In some embodiments, the obfuscation layer may be formed from a plurality of layers, that are each formed to protect against one or more visual, optical, magnetic, or electromagnetic inspection techniques.

In some embodiments, the obfuscation layer is deposited using an additive manufacturing process as an outer or encasement layer over or about the circuit layers. In an embodiment, the obfuscation layer may be a layer comprising a solid layer of material (e.g. a high-Z material). In an embodiment, the obfuscation layer may have comprised of a plurality of materials, each being deposited in a different pattern.

It should be appreciated that shielding layer or obfuscation layers may be made from materials, such as metallic materials for example, that also have desirable thermal transfer properties. In one or more embodiments herein, the shielding layer and/or obfuscation layer is configured to provide multiple functions, such as shielding, obfuscation and act as a heat sink component for conducting thermal energy from electrical components or conductors. In one or more embodiments, a shielding or obfuscation layer that also performs thermal conduction may include additional elements, such as fins, ribs, heat pipes and/or thermal interface material (e.g. thermal pastes) for example. In one or more embodiments, these heat sink elements are fabricated by additive manufacturing directly into (i.e. integral with) the shielding or obfuscation layer.

In embodiments where the shielding and/or obfuscation layers are also used for conduction of thermal energy, the layer may be configured to provide heat transfer from the underlying layer, electrical component, and/or conductor to an adjacent layer (e.g. a layer opposite the underlying layer, electrical component, and/or conductor) as shown in FIG. 7L or to the environment as shown in FIG. 7M.

In FIG. 7L, an insulation layer 740 provides electrical insulation between the layer 732 and a shielding/obfuscation layer 742 such that heat transfer Q can flow from the layer 732 to an adjacent layer 744. The layer 742 may include optional elements, such as ribs 746, or otherwise thermal pipes and conduits of fixed or variable geometries across one or more layers that extend into the adjacent layer 744 to facilitate heat transfer. In some embodiments, the optional elements may include vias that extend through multiple layers. These vias may be interconnected or be configured to extend normal to the underlying planes or encapsulation layer for example. The optional elements may include active thermal elements, such as a conduit, heat pipe, or thermal pipe through which a coolant fluid flows. In still other embodiments, other optional elements such as passive thermal elements may be used, such as a highly conductive heat sink material in combination with fins or ribs for example. In yet still other embodiments, a combination of active and passive thermal elements may be used.

In embodiments where the thermal energy is transferred to the environment, some heat sink elements such as fins 748 may extend beyond the outer surface or an encapsulation layer and are exposed to the environment (e.g. air). It should be appreciated that heat transfer may be performed by conduction, convention or radiant heat transfer.

In one or more embodiments, the structure that provides the thermal transfer function may be comprised of multiple layers, such as multiple ground layers separated by insulation layers where the material used in these layers provides for heat transfer while also providing grounding and electrical insulation respectively. In an embodiment, the insulation layers are made from a material such as aluminum nitride, a mica-based material, beryllium oxide, ceramic material, or pyrolytic graphite for example. In an embodiment, the shielding layer, obfuscation and electrical insulation layers have a thermal conductivity of between 235 W/mK and 400 W/mK.

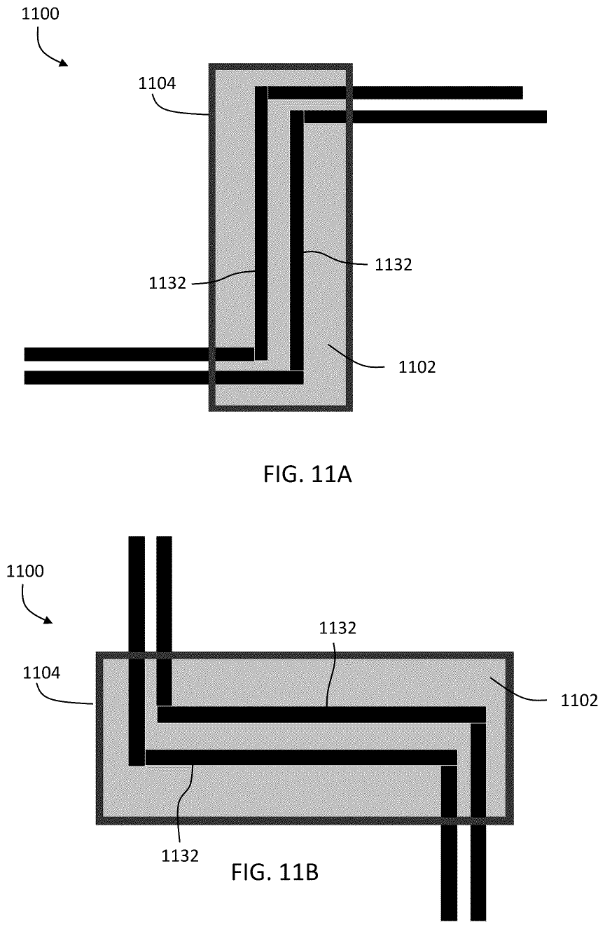

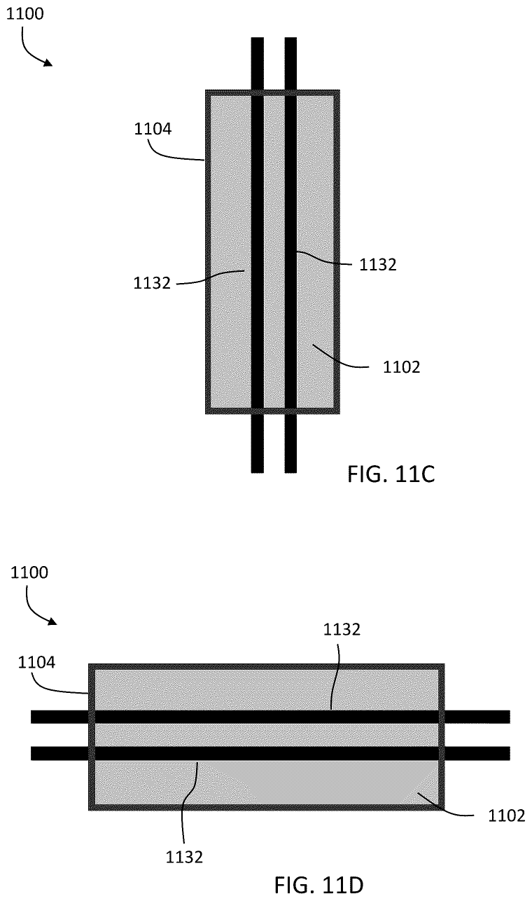

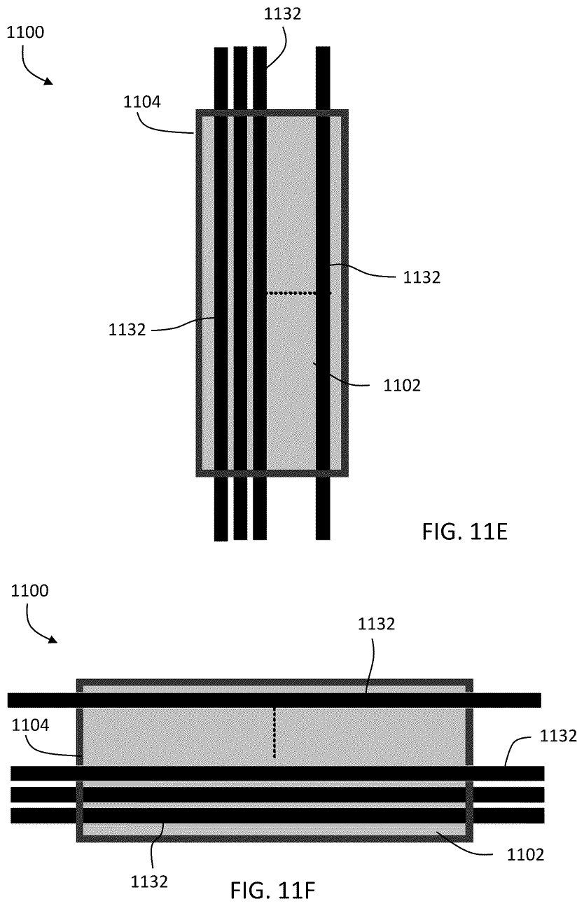

Referring now to FIGS. 11A-11F examples are shown of embodiments of a system 1100 produced using the additive manufacturing methods described herein and having a Faraday cage 1104 disposed about a base structure 1102 that encloses conductors, devices, signal traces, or busses 1132. It should be appreciated that the Faraday cage 1104 can be any of the ground planes in two or three dimensions. The Faraday cage may be a full or partial enclosure. Further, the Faraday cage does not need to be rectangular but may have other three-dimensional shapes suitable to contain the path or trajectory of one or more signal traces and perform the desired blocking of electromagnetic fields.

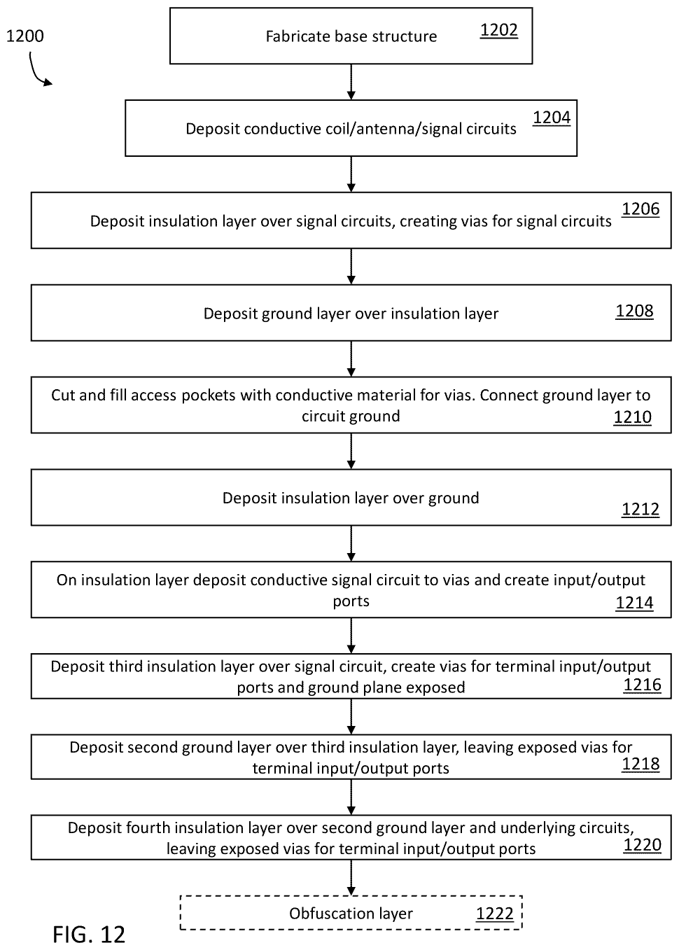

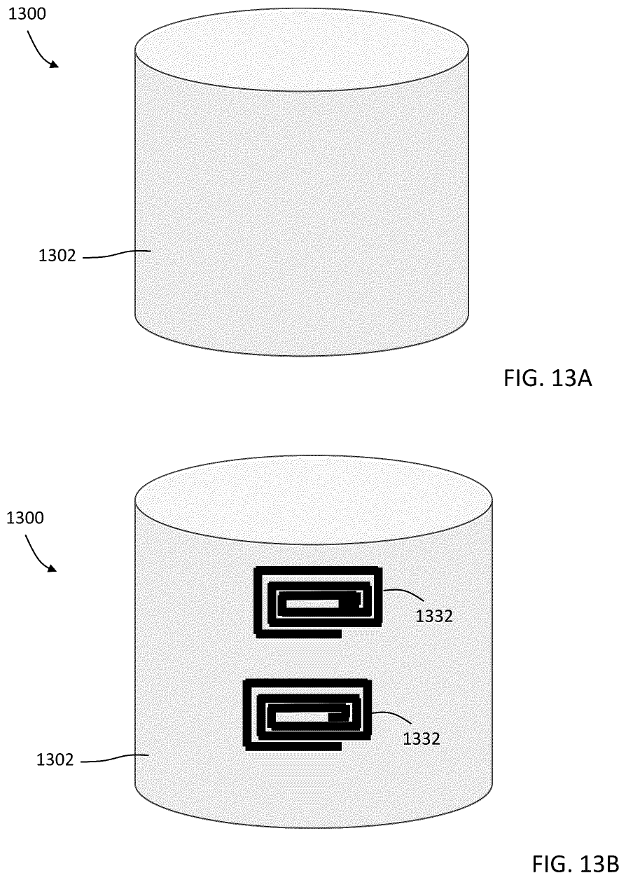

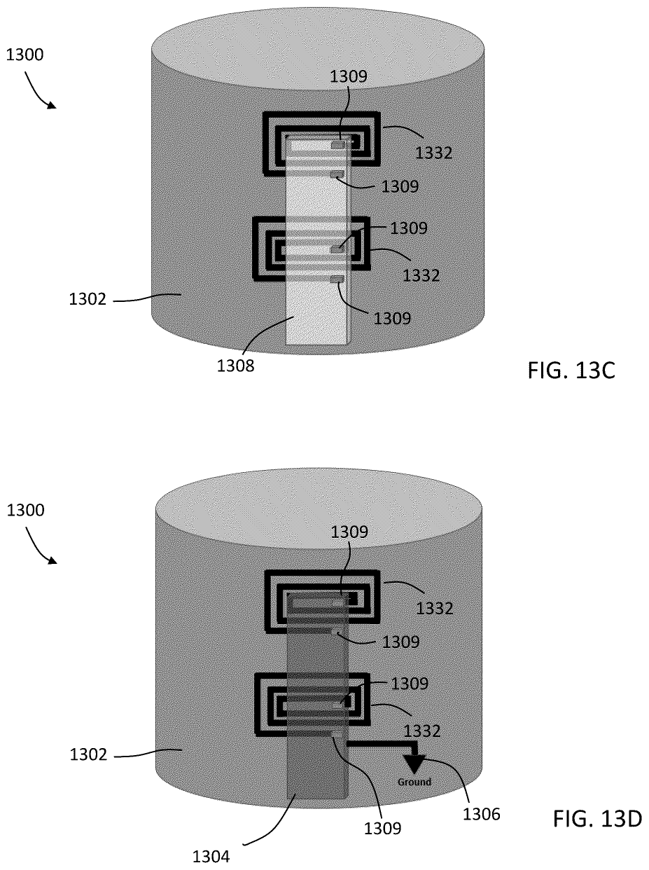

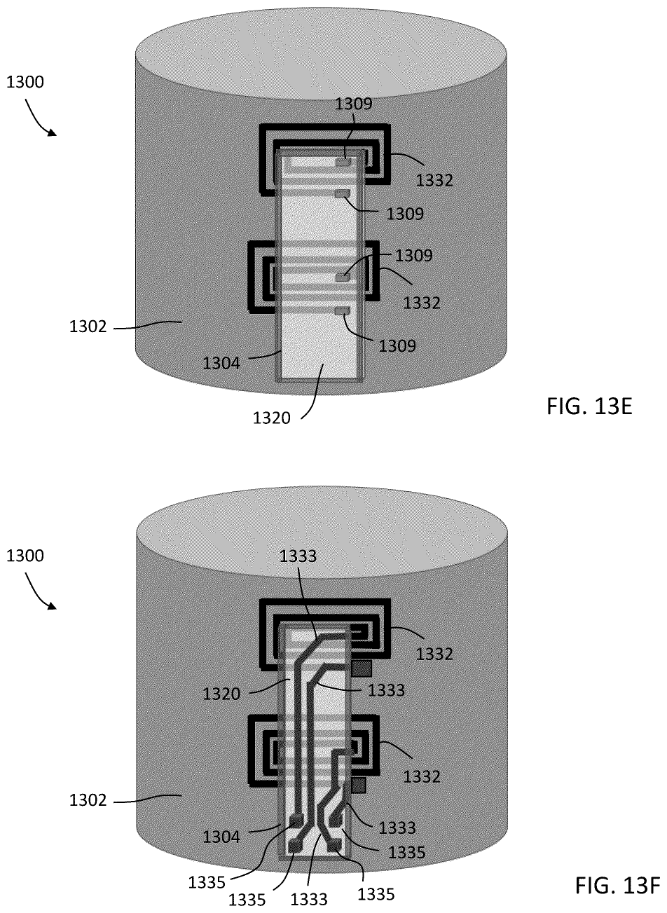

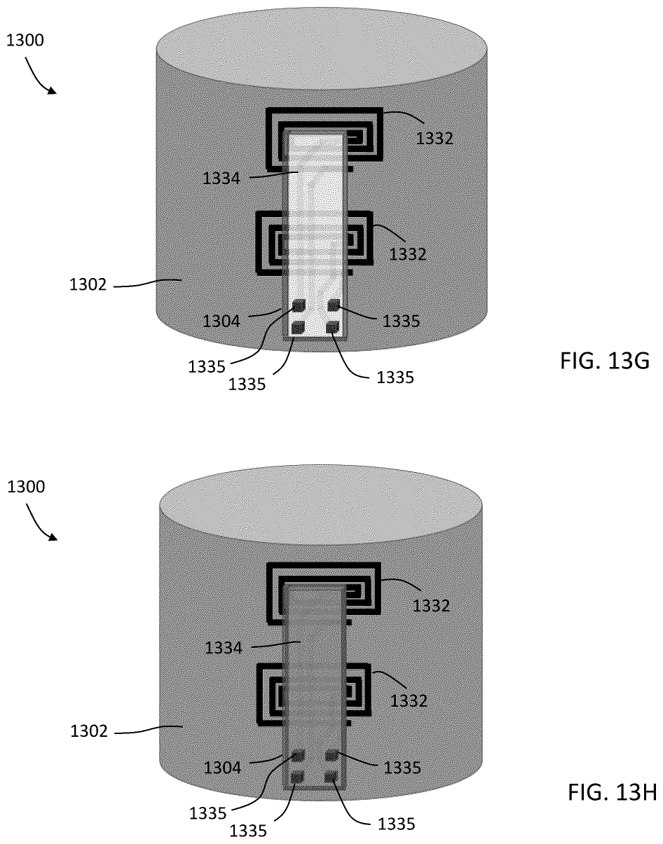

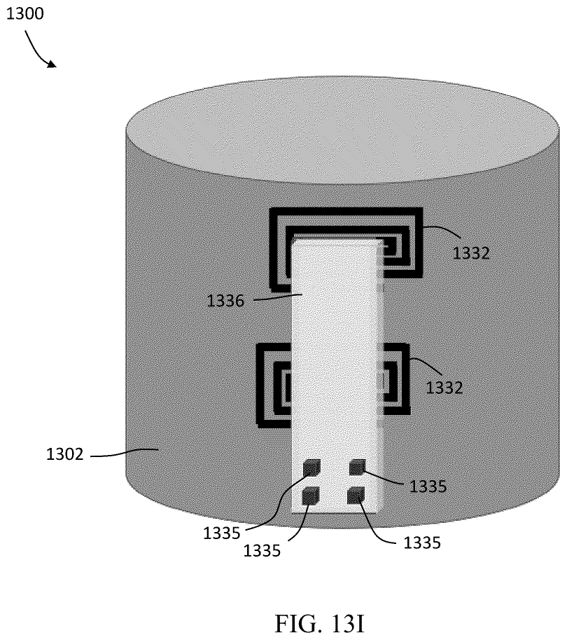

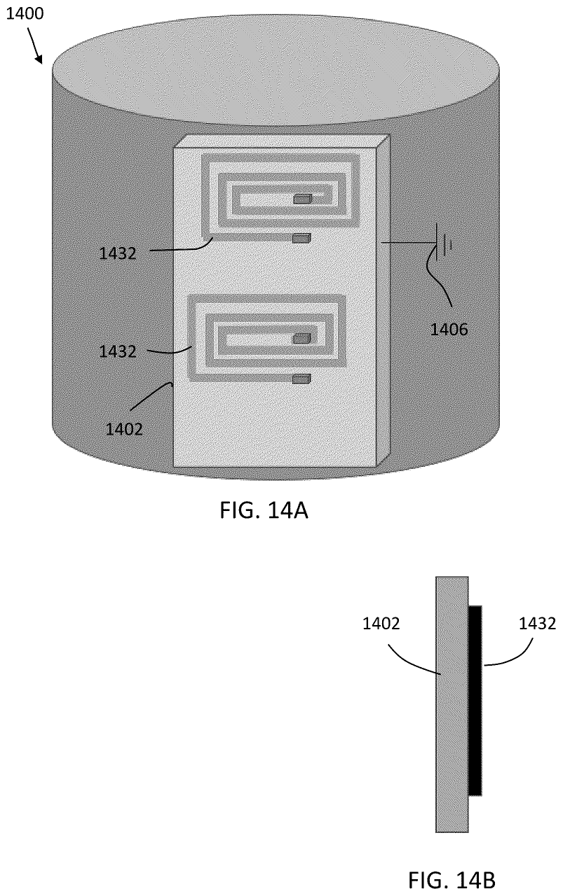

Referring now to FIG. 12 and FIGS. 13A-13I a method 1200 of fabricating a device or system 1300 having one or more circuits, signal traces, devices, arrays, or antennas using an additive manufacturing system is shown. It should be appreciated that while the method 1200 is shown as a serial process, this is for example purposes and the claims should not be so limited. In other embodiments, individual steps of the method 1200 may be performed at least partially in parallel. Still further, while the embodiment illustrated in FIG. 13A-13I shows a cylindrically shaped system, this is for example purposes and the system may have any other suitable three-dimensional structures without deviating from the teachings described herein.

It should be appreciated that the methods described herein are examples only and other geometries may be fabricated using the methods described herein without deviating from the teachings provided. For example, the method 1200 describes the fabrication of a three-plane shield. This is for example purposes and the claims should not be so limited.

The method 1200 begins in block 1202 where the base structure 1302 or base layer is fabricated using an additive manufacturing system, such as the system 600 of FIG. 6A or 6B for example. The method 1200 then proceeds to block 1204 where circuits, such as coils or antennas 1332 are deposited onto the base structure 1302. In an embodiment, the base structure 1302 is made from an electrically insulative material and the antennas 1332 are fabricated using an electrically conductive material for example. It should be appreciated that the antennas 1332 may have a three-dimensional shape that varies to conform with the shape of the base structure 1302.

It should further be appreciated that while the embodiment of FIG. 13B-13I illustrate the device 1332 as being a coil or antenna, this is for example purposes and the claims should not be so limited. In other embodiments the device 1332 may be an electrically noisy device, such as a motor for example, and supporting circuitry (e.g. a drive circuit) and the surrounding structure is fabricated around it in a shielding configuration.

The method 1200 then proceeds to block 1206 where a first insulation layer 1308 is deposited over at least a portion of the antennas 1332. The first insulation layer 1308 is formed with vias 1309 formed therein. It should be appreciated that in other embodiments, the first insulation layer 1308 is formed over the entirety of the antennas 1332. The first insulation layer 1308 is formed from an electrically insulating material. Further, the first insulation layer 1308 may have a three-dimensional shape, such as to conform with the outer surface of the base structure 1302.

The method 1200 then proceeds to block 1308 where a shielding or conductive grounded layer 1304 is deposited on the first insulation layer 1308. In an embodiment, additional steps may be performed in block 1210 to cut and fill access pockets with conductive material for circuit vias 1309 that do not contact ground plane 1304. The conductive grounded layer 1304 is connected to a circuit ground 1306. The method 1200 then proceeds to block 1212 where a second insulation layer is deposited over and/or on to the conductive grounded layer 1304. In an embodiment, perimeter regions of the second insulation layer 132 are smaller than the underlying first conductive grounded layer 1304 to leave portions of the first conductive grounded layer 1304 exposed. In an embodiment, the vias remain uncovered or exposed to allow signal traces 1333 to be deposited in block 1214. In block 1214 conductive signal traces 1333 are routed between the vias 1309 circuit terminal input/output ports 1335. In an embodiment, the input/output ports 1335 may be fabricated by additive manufacturing using the same material as signal traces 1333. In other embodiments, the input/output ports 1335 may be a component that is inserted on to the second insulation layer 1320, such as with a pick and place device for example.

The method 1200 then proceeds to block 1216 where a third insulation layer 1334 is deposited over underlying insulation layer and signal traces 1333. The third insulation layer 1334 is sized to leave exposed the conductive ground layer 1304 along perimeter and vias for terminal input/output ports 1335. The method 1200 then proceeds to block 1218 where a second conductive grounded layer 1322 is deposited over the underlying signal traces 1333 and third insulation layer 1334, leaving exposed vias for terminal input/output ports 1335.

The method 1200 then proceeds to block 1220 where a fourth final insulation layer 1336 is deposited over the second conductive grounded layer 1334 and underlying signal traces 1333, leaving exposed vias for terminal input/output ports 1335. When this step is completed, all conductive interconnection circuits are enclosed within grounded structure mitigating interference effects of signal interconnects. In some embodiments, sensors (not shown) within the circuit may saturate at 0.01 microvolts and are thus highly susceptible to external noise. It should be appreciated that the resulting structure may be used to provide a radio frequency shield to protect the signal traces 1333 and antennas 1332 against external or coupled noise signals.

In an embodiment, the method 1200 proceeds to block 1222 where an optional obfuscation layer is deposited over the fourth insulation layer 1336. In an embodiment, the obfuscation layer is comprised of one or more layers that include materials (e.g. high-Z materials) that inhibit the use of techniques, such as electron microscope or tomography for example, for measuring or determining the underlying structure. In an embodiment, the obfuscation layer may be made from a material that facilitates heat transfer from underlying or internal layers, electrical components, and/or conductors to other layers or the external environment.

It should be appreciated while the embodiment of FIGS. 13A-13I illustrated a particular system 1300, this is for example purposes and the method of FIG. 12 may be modified to fabricate other systems without deviating from the teachings herein. For example, the base structure may have a semi-spherical shape, or any other three-dimensional shape that may be fabricated by an additive manufacturing system, with a plurality of coils or antennas (such as is shown FIG. 3A, FIG. 3B for example). For further example, in the embodiment of FIG. 14, a system 1400 is provided having a shielding and insulation structure 1402 that extends beyond the circuit 1432 (e.g. axially and circumferentially). The shielding and insulation structure 1402 is coupled to ground 1406.

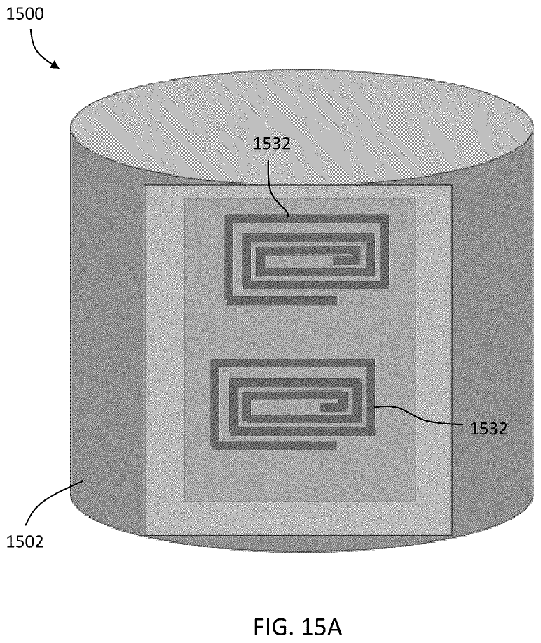

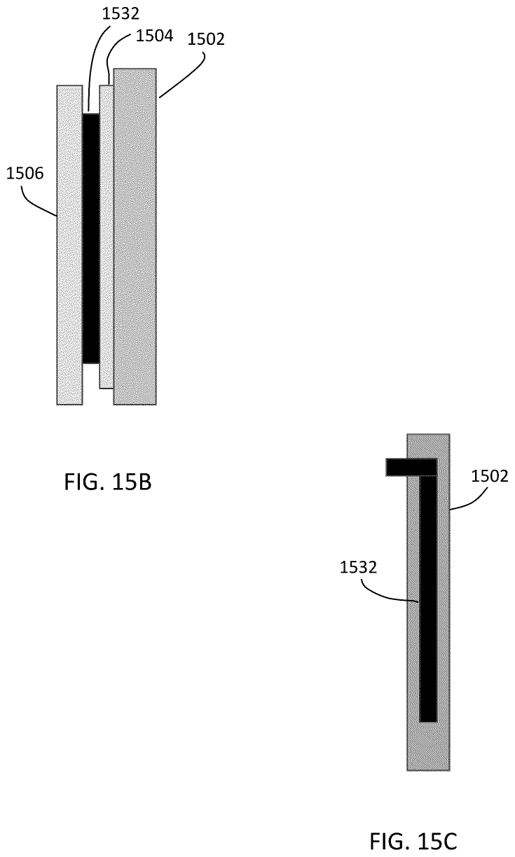

In still further embodiments, such as is shown in FIGS. 15A-15C, additional examples of structures are shown that may be fabricated through additive manufacturing methods described herein. The system 1500 includes a base structure 1502 and circuits, such as antennas 1532. In this embodiment, the antennas are shielded and insulated by a first shielding and insulation layer 1504 arranged between the antennas 1532 and the base structure 1502. The assembly further includes a second shielding and insulation layer 1506 arranged on an opposite side of the antennas 1532 from the first shielding and insulation layer 1504. In this way the antennas 1532 are shielded on both sides of the circuit. In still another embodiment shown in FIG. 15C, the antenna 1532 may be embedded in the base structure 1502. It should be appreciated that system shown in FIG. 15C may be shielding and insulation layers formed internally to the base structure 1502 and/or on the external surface of the base structure 1502.

Embodiments herein provide advantages in allowing the fabrication through additive manufacturing of systems that include integrated circuits, devices, antennas, signal circuits and busses as well as electro-mechanical or electro-chemical systems. Further embodiments provide advantages in allows the fabrication of systems that include integrated circuits, devices, antennas, signal circuits and busses as well as electro-mechanical or electro-chemical systems that are shielded to prevent or reduce the transmission of external signals such as noise into the circuit. Similarly, the shielding methods described my also protect the electrical components or device from external or coupled signals and noise to sensitive components within the additively manufactured target object.

It should be appreciated that the method of FIG. 12 may be used to fabricate through additive manufacturing any of the assemblies or configurations shown in FIGS. 3A-5D or FIGS. 7A-11F without deviating from the teachings provided herein.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It should also be noted that the terms “first”, “second”, “third”, “upper”, “lower”, and the like may be used herein to modify various elements. These modifiers do not imply a spatial, sequential, or hierarchical order to the modified elements unless specifically stated.

Various embodiments of the invention are described herein with reference to the related drawings. Alternative embodiments of the invention can be devised without departing from the scope of this invention. Various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. Moreover, the various tasks and process steps described herein can be incorporated into a more comprehensive procedure or process having additional steps or functionality not described in detail herein.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” may be understood to include any integer number greater than or equal to one, i.e. one, two, three, four, etc. The terms “a plurality” may be understood to include any integer number greater than or equal to two, i.e. two, three, four, five, etc. The term “connection” may include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of +8% or 5%, or 2% of a given value.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instruction by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments described herein.

While the disclosure is provided in detail in connection with only a limited number of embodiments, it should be readily understood that the disclosure is not limited to such disclosed embodiments. Rather, the disclosure can be modified to incorporate any number of variations, alterations, substitutions or equivalent arrangements not heretofore described, but which are commensurate with the spirit and scope of the disclosure. Additionally, while various embodiments of the disclosure have been described, it is to be understood that the exemplary embodiment(s) may include only some of the described exemplary aspects. Accordingly, the disclosure is not to be seen as limited by the foregoing description, but is only limited by the scope of the appended claims.

What is claimed is:

1. A method of fabricating an object comprising:
fabricating a base structure using an additive manufacturing process;
depositing or fabricating a first electrical component on or in the base structure; and
depositing with the additive manufacturing process at least one material to define a first ground layer on the base structure that is associated with the first electrical component and positioned to reduce electrical noise, RF signals, microwave or magnetic field interference from being transmitted therethrough.

2. The method of claim 1, wherein the first electrical component is a coil, an antenna, a conductor, a buss, a signal circuit, an electro-mechanical device, electro-chemical device, an integrated circuit or a field programmable gate array.

3. The method of claim 2, further comprising depositing at least one insulation material over the first electrical component with the additive manufacturing process, the layer including at least one via.

4. The method of claim 3, further comprising cutting access pockets for the via, and connecting the ground layer to a ground circuit.

5. The method of claim 4, further comprising depositing a second insulation layer over the first ground layer with the additive manufacturing process.

6. The method of claim 5, further comprising depositing a second circuit material to define a signal circuit with the additive manufacturing process, the signal circuit having an input port and an output port.

7. The method of claim 6, further comprising depositing a third insulation layer over the signal circuit with the additive manufacturing process, the third insulation layer being formed with at least two vias associated with the input port and the output port.

8. The method of claim 7, further comprising depositing a second ground layer over the third insulation layer with the additive manufacturing process, the second ground layer having at least two vias aligned with the input port and the output port.

9. The method of claim 8, further comprising depositing a fourth insulation layer over the second ground layer with the additive manufacturing process, the fourth insulation layer having at least two vias aligned with the input port and the output port.

10. The method of claim 3, wherein the first ground layer is made from one or more materials selected from a group comprising: silver, copper, lead, graphite, graphene, and pyrolytic carbon.

11. The method of claim 1, wherein the first layer is formed with a three-dimensional shape.

12. The method of claim 3, further comprising depositing a first ground layer associated with the first electrical component with the additive manufacturing process.

13. The method of claim 12, wherein the first ground layer is disposed on at least two sides of the first electrical component.

14. The method of claim 13, wherein the first ground layer is disposed on at least three sides of the first electrical component.

15. The method of claim 14, wherein the first ground layer is on at least fourth sides of the first electrical component.

16. The method of claim 15, wherein the first ground layer encloses the first electrical component.

17. The method of claim 12, wherein the first ground layer is disposed within the base structure.

18. The method of claim 17, wherein the first electrical component is disposed within the base structure.

19. The method of claim 18, wherein the first electrical component is enclosed by the first ground layer within the base structure.

20. The method of claim 19, wherein at least one of the first electrical component and first ground layer have an cross-sectional geometry that varies in three-dimensional space.

21. The method of claim 1, further comprising conducting thermal energy through the first ground layer.

22. The method of claim 1, wherein the transferring thermal energy includes the transferring of thermal energy via ribs extending from the first ground layer.

23. A method of fabricating an object comprising:
fabricating a base structure using an additive manufacturing process;
depositing a first electrical component or electrical circuit on or adjacent to the first insulation layer;
depositing a first insulation layer adjacent the grounding layer with the additive manufacturing process;
depositing a grounding layer adjacent the insulation layer using the additive manufacturing process, the grounding layer being electrically coupled to the first electrical component or electrical circuit; and
depositing with the additive manufacturing process at least one second insulation layer adjacent the grounding layer, the at least one second insulation layer being positioned to reduce electrical noise and/or magnetic field interference from being transmitted therethrough.

24. The method of claim 23, further comprising:
forming at least one first via through the at least one second insulation layer;
depositing conductive materials in the at least one first via; and
electrically coupling the grounding layer to the first electrical component or electrical circuit through the at least one first via.

25. The method of claim 24, further comprising:
forming at least one second via in the second insulation layer with the additive manufacturing process;
filling the at one second via with a conductive material; and
depositing a signal circuit layer on the second insulation layer, the signal circuit being electrically coupled to the at least one second via.

26. The method of claim 25, further comprising:
depositing a third insulation layer on the signal circuit layer with the additive manufacturing process, the third insulation layer being formed with at least one input/output port via;
depositing a second grounding layer on the third insulation layer, the second grounding layer leaving the at least one input/output port exposed; and
depositing a fourth insulation layer on the second grounding layer with the additive manufacturing process.

27. The method of claim 26, further comprising transferring thermal energy from the signal circuit layer via the third insulation layer, the second grounding layer and the fourth insulation layer to the environment.

28. The method of claim 26, wherein the third insulation layer and fourth insulator are formed from a material that is electrically insulator and has high thermal conductivity.
